(19) United States
(12) Patent Application Publication
(10) Pub. No.: US 2026/0367513 A1
(43) Pub. Date: Nov. 19, 2026

(54) PHOTOSENSITIVE RESIN COMPOSITION, DRY FILM, CURED PRODUCT, PRINTED CIRCUIT BOARD, AND LAMINATE

(71) Applicant: TAIYO INK MFG. CO.,(KOREA)LTD., Ansan-si, Gyeonggi-do (KR)

(72) Inventors: Jongchul KWON, Anyang-si, Gyeonggi-do (KR); Seokbong LIM, Incheon (KR); Youngho SA, Ansan-si, Gyeonggi-do (KR); Byeongjun CHOI, Incheon (KR); Kangsoo KIM, Suwon-si, Gyeonggi-do (KR)

(21) Appl. No.: 19/118,358

(22) PCT Filed: Mar. 28, 2024
(86) PCT No.: PCT/KR2024/003983

§ 371 Date: Apr. 4, 2025

(30) Foreign Application Priority Data
Mar. 31, 2023 (KR) 10-2023-0042635
Mar. 27, 2024 (KR) 10-2024-0041704

(51) Int. Cl. G03F 7/029; C07F 9/30; C08G 65/48; G03F 7/032; G03F 7/033

(52) U.S. Cl. CPC G03F 7/029; C07F 9/304; C08G 65/48; G03F 7/032; G03F 7/033

(57) ABSTRACT

A photosensitive resin composition includes: (A) a carboxyl group-containing resin not containing an aromatic ring; (B) an inorganic filler; and (E) a photopolymerization initiator of a trimethylbenzoyl phosphine oxide group-containing compound having at least one P—O band. Through the photosensitive resin composition, the outgas of the photopolymerization initiator can be reduced, and a firing process after a reflow process can be omitted to increase reflectance, thus solving the problems associated with power consumption, the HAST resistance and the reflectance after the HAST test are high, and the reduction in reflectance under the conditions of high temperature/high humidity can be suppressed, and consequently, these characteristics of the photosensitive resin composition enable a produced solder resist to exert excellent effects, so that the photosensitive resin composition can efficiently provide opening hole to the solder resist and facilitate the implementation of an efficient backlight unit through a solder resist with high reflectance.

### TECHNICAL FIELD

The present disclosure relates to a photosensitive resin composition, a dry film, a cured product, a printed circuit board, and a laminate, wherein the dry film has a photosensitive resin layer formed by applying and drying the photosensitive resin composition on a first film, the cured product is obtained by curing a photosensitive resin layer of the dry film, and the printed circuit board and laminate each include the cured product.

### BACKGROUND

As for printed circuit boards used in electronic devices and the like, in order to prevent solder from attaching to unnecessary parts and prevent a circuit conductor from being exposed and corroded by oxidation or humidity when electronic components are mounted on the printed circuit boards, a solder resist layer is generally formed on the area except for connection holes of the board with circuit patterns.

With recent high precision and high density of printed circuit boards according to light-weighting and miniaturization of electronic devices, recent solder resist layers are usually formed by applying a photosensitive resin composition to a substrate, forming a pattern through exposure and development, and then main-curing the patterned resin through heating or light irradiation, so-called photo solder resist.

Such a liquid photosensitive resin composition described above contains a solvent, necessitating repeated printing and composition drying processes during production, resulting in long working times and environmental unfriendliness.

Rather than using the liquid photosensitive resin composition, there has been a proposal to use a so-called photosensitive dry film for forming a solder resist layer, which enables the omission of a drying process after applying the composition. The lamination using the dry film reduces the working time, thus significantly shortening the manufacturing process and increasing productivity while enabling efficient utilization of a solder resist layer even on thin film boards.

Such a dry film typically includes a laminated structure in which a solder resist layer as a photosensitive resin layer is formed on a first film as a substrate and a second film for purposes of protection or the like is bonded to the layer. During use, the dry film is heat-pressed on a circuit board after the peeling off the second film, and exposure is performed on the first film, and the first film is peeled off, followed by development, thereby forming a patterned solder resist layer. Compared with the use of a liquid photosensitive resin composition as described above, the use of a dry film for solder resist layer formation enables not only the omission of a composition drying process but also the improvement in hole filling properties on the recesses of the board surface due to the difficulty in the incorporation of air bubbles between the board and the solder resist layer, resulting from the press of the dry film on the circuit board. Additionally, the use of a dry film for solder resist layer formation ensures excellent flatness of a film to enable the efficient mounting of a chip, leads to high resolution.

Meanwhile, a white solder resist layer has a higher reflectance than colored solder resist layers, and therefore, when the solder resist layer is formed using a dry film by the same method as above, light is reflected from the surface of the solder resist layer during exposure, so light is difficult to penetrate to the lower part of the solder resist layer, and a phenomenon of the upper part enlarging compared with the lower part (halation) occurs on the surface, causing a difficulty in pattern implementation (e.g., see Patent Document 1).

A solder resist layer also functions as a permanent protective film for circuit boards, so that solder resist compositions are required to have a variety of performances, such as alkali developability and solder heat resistance.

Furthermore, it is crucial for a white solder resist layer to possess high reflectance, minimize the reduction in reflectance during manufacturing, and prevent yellowing of a cured product when exposed to heat or light, in addition to meeting the requirements as a general solder resist layer.

There is a need for: a photosensitive resin composition that meets not only the fundamental requirements for a solder resist layer but also additional requirements for a white solder resist layer, has a higher reflectance compared with the prior art and excellent yellowing resistance; a dry film including a solder resist layer that can solve distinctive problems arising during the manufacturing procedure of the solder resist layer; and a method of manufacturing printed circuit boards.
(Patent Document 1) Korean Patent Publication No. 10-2022-0086524

### SUMMARY

A conventional photopolymerization initiator (e.g., 2,4,6-trimethylbenzoyldiphenyl phosphine oxide (TPO)) contained in photosensitive resin compositions forming solder resists generates a significant amount of outgas, and when this outgas diffuses into an adjacent silicone encapsulant, a transparent silicone encapsulant may undergo yellowing, thereby reducing reflectance and causing incomplete curing of silicone encapsulant. These drawbacks cause problems with long-term reliability of boards. Moreover, the photopolymerization initiator may be transferred not only to the silicone encapsulant but also to adjacent boards.

In order to remove the outgas of the photopolymerization initiators, the addition of a firing process (e.g., curing at 150 °C for 6 hours) after a reflow process (e.g., at 260 °C for 10 seconds) has been contemplated, but this firing process significantly reduced reflectance, resulting in an increase in power consumption in order to enhance reflectance after chip mounting when the photopolymerization initiator was used for a backlight unit or similar purposes. In other words, the number of processes may be increased and the reflectance may also be reduced.

Additionally, a protective film (PF) may be placed on the solder resist layer in order to remove the photopolymerization initiator, before such a firing process. The protective film is used to remove outgas of the photopolymerization initiator as much as possible after the preparation of the solder resist and before the subsequent firing process, and is eliminated by peeling before the firing process. The protective film has been used for purpose of removing the photopolymerization initiator since the protective film can efficiently remove the photopolymerization initiator due to its high affinity for the photopolymerization initiator. However, this necessitated two processes of process associated with the use of such a protective film and the firing process and did not solve the reduction in reflectance.

Various embodiments of the present disclosure provide a photosensitive resin composition including: (A) a carboxyl group-containing resin not containing an aromatic ring; (B) an inorganic filler and/or (C) a mercapto-modified (meth)acrylate; and (E) a photopolymerization initiator of a trimethylbenzoyl phosphine oxide group-containing compound having at least one P—O band.

According to the photosensitive resin composition of the present disclosure, the outgas of the photopolymerization initiator can be significantly reduced to solve yellowing and incomplete curing of a silicone encapsulant and improve the reaction rate of the silicone encapsulant. Furthermore, the amount of the outgas generated from the photopolymerization initiator can be suppressed to reduce the amount of outgas transferred to the protective film, and a firing process after a reflow process can be omitted to increase reflectance, thus solving the problems associated with power consumption. Furthermore, the photosensitive resin composition of the present disclosure can exhibit excellent highly accelerated stress test (HAST) resistance, high reflectance after reflowing, UV testing or HAST testing and suppress the reduction in reflectance under high temperature/high humidity conditions. These characteristics of the photosensitive resin composition of the present disclosure enable a produced solder resist to exert excellent effects.

Various embodiments of the present disclosure provide a dry film, a cured product, a printed circuit board, and a laminate each using the photosensitive resin composition.

In accordance with an aspect of the present disclosure relates to a photosensitive resin composition.

A photosensitive resin composition according to one embodiment of the present disclosure may include: (A) a carboxyl group-containing resin not containing an aromatic ring; (B) an inorganic filler; and (E) a photopolymerization initiator of a trimethylbenzoyl phosphine oxide group-containing compound having at least one P—O band.

In the photosensitive resin composition according to an embodiment of the present disclosure, (E) the photopolymerization initiator of a trimethylbenzoyl phosphine oxide group-containing compound having at least one P—O band may include a *—C(═O)—P(═O)R₁—O—*′ moiety (where, R₁ is an alkyl group of 1 to 20 carbon atoms, an alkenyl group of 2 to 20 carbon atoms, an alkynyl group of 2 to 20 carbon atoms, or a cyclic group of 5 to 20 carbon atoms).

In the photosensitive resin composition according to an embodiment of the present disclosure, (E) the photopolymerization initiator of a trimethylbenzoyl phosphine oxide group-containing compound having at least one P—O band may be a trimethylbenzoyl phosphine oxide group-containing polymer.

In the photosensitive resin composition according to an embodiment of the present disclosure, the trimethylbenzoyl phosphine oxide group-containing polymer may have a weight average molecular weight (Mₙ) of 900 g/mol or more.

In the photosensitive resin composition according to an embodiment of the present disclosure, the trimethylbenzoyl phosphine oxide group-containing polymer may be represented by Chemical Formula 1 below:

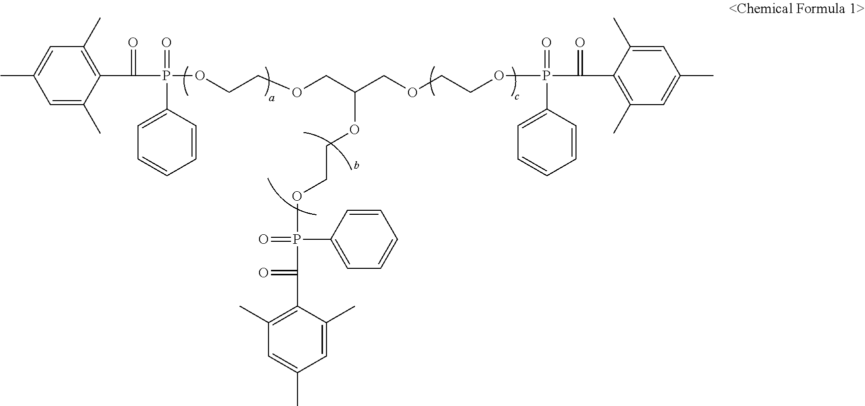

a=0 to 100, b=0 to 100, and c=0 to 100.

In the photosensitive resin composition according to an embodiment of the present disclosure, (E) the photopolymerization initiator of a trimethylbenzoyl phosphine oxide group-containing compound having at least one P—O band may include an alkoxy group.

In the photosensitive resin composition according to an embodiment of the present disclosure, (E) the photopolymerization initiator of a trimethylbenzoyl phosphine oxide group-containing compound having at least one P—O band may include an ethoxy group.

In the photosensitive resin composition according to an embodiment of the present disclosure, (E) the photopolymerization initiator of a trimethylbenzoyl phosphine oxide group-containing compound having at least one P—O band may be represented by Chemical Formula 2 below:

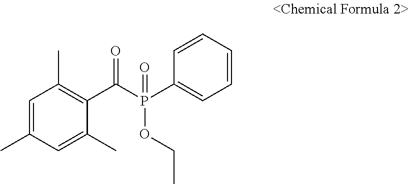 [SMILES: CCOP(=O)(C(=O)c1c(C)cc(C)cc1C)c1ccccc1]

In the photosensitive resin composition according to an embodiment of the present disclosure, the content of (E) the photopolymerization initiator of a trimethylbenzoyl phosphine oxide group-containing compound having at least one P—O band may be 0.01 to 10 wt % relative to the total weight of the composition.

In the photosensitive resin composition according to an embodiment of the present disclosure, (A) the carboxyl group-containing resin not containing an aromatic ring may have an unsaturated double bond.

In the photosensitive resin composition according to an embodiment of the present disclosure, (D) the photosensitive resin composition may further include a resin containing an aromatic ring.

In the photosensitive resin composition according to an embodiment of the present disclosure, (D) the resin containing an aromatic ring may be a melamine resin, a silicone resin, or a resin having a styrene backbone.

In the photosensitive resin composition according to an embodiment of the present disclosure, the photosensitive resin composition may further include (C) a mercapto-modified (meth)acrylate.

In the photosensitive resin composition according to an embodiment of the present disclosure, the photosensitive resin composition may further include (F) a silane coupling agent.

In the photosensitive resin composition according to an embodiment of the present disclosure, the photosensitive resin composition may further include (G) a resin having a urethane bond.

In the photosensitive resin composition according to an embodiment of the present disclosure, the content of outgas measured by thermal desorption spectroscopy (TDS) and gas chromatography-mass spectrometry (GC-MS) for the photosensitive resin composition may be 1,000 ppm or less relative to (E) the photopolymerization initiator of a trimethylbenzoyl phosphine oxide group-containing compound having at least one P—O band.

In the photosensitive resin composition according to an embodiment of the present disclosure, the content of phosphorous may be 500 to 5000 ppm.

A photosensitive resin composition according to one embodiment of the present disclosure may include: (A) a carboxyl group-containing resin not containing an aromatic ring; (C) a mercapto-modified (meth)acrylate; and (E) a photopolymerization initiator of a trimethylbenzoyl phosphine oxide group-containing compound having at least one P—O band.

In the photosensitive resin composition according to an embodiment of the present disclosure, the photosensitive resin composition may further include (D) a resin containing an aromatic ring.

In the photosensitive resin composition according to an embodiment of the present disclosure, the photosensitive resin composition may further include (F) a silane coupling agent.

In the photosensitive resin composition according to an embodiment of the present disclosure, the photosensitive resin composition may further include (G) a resin having a urethane bond.

A dry film according to one embodiment of the present disclosure may have a photosensitive resin layer formed by applying and drying the photosensitive resin composition onto a first film.

A cured product according to one embodiment of the present disclosure may be obtained by curing the photosensitive resin composition or a photosensitive resin layer for a dry film obtained from the photosensitive resin composition.

A printed circuit board according to one embodiment of the present disclosure may include the cured product as a solder resist.

A printed circuit board according to one embodiment of the present disclosure may further include a silicone encapsulant disposed on the solder resist.

In the printed circuit board according to an embodiment of the present disclosure, the silicone encapsulant may include an upper encapsulant region and a lower encapsulant region, and the content of (E) the photopolymerization initiator of a trimethylbenzoyl phosphine oxide group-containing compound having at least one P—O band included in at least one of the upper encapsulant region or the lower encapsulant region may be 1,000 ppm or less relative to the content of (E) the photopolymerization initiator of a trimethylbenzoyl phosphine oxide group-containing compound having at least one P—O band included in the solder resist.

A laminate according to one embodiment of the present disclosure may include: the cured product; and a protective film.

In the laminate according to an embodiment of the present disclosure, the content of (E) the photopolymerization initiator of a trimethylbenzoyl phosphine oxide group-containing compound having at least one P—O band included in the protective film may be 1,000 ppm or less relative to the content of (E) the photopolymerization initiator of a trimethylbenzoyl phosphine oxide group-containing compound having at least one P—O band included in the solder resist.

According to the present disclosure in some embodiments, as for the photosensitive resin composition, the outgas of the photopolymerization initiator can be significantly reduced to solve yellowing and incomplete curing of a silicone encapsulant and improve the reaction rate of the silicone encapsulant. Furthermore, the amount of the outgas transferred to the protective film from the photopolymerization initiator can be reduced, and a firing process after a reflow process can be omitted to increase reflectance, thus solving the problems associated with power consumption. Furthermore, the HAST resistance and the reflectance after the HAST test are high, and the reduction in reflectance under the conditions of high temperature/high humidity can be suppressed. These characteristics of the photosensitive resin composition of the present disclosure enable a produced solder resist to exert excellent effects.

For example, the photosensitive resin composition according to an aspect of the present disclosure can obtain an excellent reflectance maintaining effect by further including titanium oxide as an inorganic filler.

According to the present disclosure in some embodiments, there can also be provided a dry film, a cured product, a printed circuit board, and a laminate each using the photosensitive resin composition.

### BRIEF DESCRIPTION OF DRAWINGS

FIGS. 1A and 1B are images showing BHAST test results of dry films using photosensitive resin compositions of Comparative Example 1 and Example 3, respectively.

### DETAILED DESCRIPTION

Hereinafter, various aspects of the present disclosure are described.

### [Photosensitive Resin Composition]

An aspect of the present disclosure is directed to a photosensitive resin composition including: (A) a carboxyl group-containing resin not containing an aromatic ring; (B) an inorganic filler; and (E) a photopolymerization initiator selected from trimethylbenzoyl phosphine oxide group-containing compounds having at least one P—O band.

Another aspect of the present disclosure is directed to a photosensitive resin composition including: (A) a carboxyl group-containing resin not containing an aromatic ring; (C) a mercapto-modified (meth)acrylate; and (E) a photopolymerization initiator of a trimethylbenzoyl phosphine oxide group-containing compound having at least one P—O band.

The photosensitive resin composition can suppress outgassing and exhibit excellent silicone encapsulant reaction rates, reflectance, and HAST resistance.

For example, the photosensitive resin composition may be a composition that is cured to form a solder resist.

Hereinafter, each component of the photosensitive resin composition is described in detail.

### [(A) Carboxyl Group-Containing Resin not Containing Aromatic Ring]

In a photosensitive resin composition according to an embodiment of the present disclosure, (A) a carboxyl group-containing resin not containing an aromatic ring (hereinafter, “resin (A)”) may be a resin that is cured by irradiation with active energy rays to exhibit electrical insulation. Examples of the aromatic ring may include a benzene ring, a pyridine ring, a pyrimidine ring, a triazine ring, and the like.

The resin (A) can be alkali-developed by containing a carboxyl group, and has excellent resistance to discoloration or yellowing when receiving heat or UV energy, due to the absence of an aromatic ring. In addition, combining the resin (A) with the inorganic filler (B) yields a high reflectance, a smaller reduction in reflectance after a reflow process, and a smaller reduction in reflectance after being subject to a 3000-hour blue light test. Therefore, the composition containing the resin (A) has a smaller reduction in reflectance resulting from discoloration and yellowing compared with other white ink compositions and shows excellent yellowing resistance. For example, compared with the compared to the resin (A) not containing an aromatic ring, carboxyl group-containing resins containing an aromatic ring may show a relatively low initial reflectance of a cured product and undergo a significantly large reduction in reflectance when subjected to heat, UV, BHAST, and 85 °C/85% tests. The reason is that the aromatic ring is deformed by the heat, UV, BHAST, and 85 °C/85% tests, greatly contributing to the reduction in reflectance.

For example, the resin (A) may have an unsaturated double bond. The resin (A) can be radical-cured by ultraviolet rays, electron beams, or heat, due to the presence of the saturated double bond therein.

The resin (A) is not particularly limited as long as it contains a carboxyl group but does not contain an aromatic ring. An example thereof may be a photosensitive carboxyl group-containing resin having at least one photosensitive unsaturated double bond itself or a carboxyl group-containing resin not having a photosensitive unsaturated double bond.

For example, any one that does not have an aromatic ring (any of oligomers or polymers) from the resins listed below may be suitably used:
(1) a carboxyl group-containing resin obtained by copolymerization of an unsaturated carboxylic acid and a compound having an unsaturated double bond;
(2) a photosensitive carboxyl group-containing resin obtained by reacting a carboxyl group-containing (meth)acrylic copolymer resin with a compound having an oxirane ring and an ethylenically unsaturated group in one molecule;
(3) a photosensitive carboxyl group-containing resin obtained by reacting unsaturated monocarboxylic acid with a copolymer of a compound having an unsaturated double bond and a compound having one unsaturated double bond and one epoxy group in each molecule and reacting a secondary hydroxyl group-saturated or unsaturated polybasic acid anhydride produced by the reaction; and
(4) a resin containing a photosensitive hydroxyl group and a carboxyl group, which is obtained by reacting a hydroxyl group-containing polymer and a saturated or unsaturated polybasic acid anhydride and then reacting each compound having one epoxy group and an unsaturated double bond in one carboxylic acid molecule generated by the reaction.

For example, the resin (A) may be a copolymer resin having a carboxyl group, which is obtained by reacting (a) a carboxyl group-containing (meth)acrylic copolymer resin, which is the photosensitive carboxyl group-containing resin (2), with (b) a compound having an oxirane ring and an ethylenically unsaturated group in one molecule.

For example, the carboxyl group-containing (meth)acrylic copolymer resin (a) may be obtained by copolymerizing a (meth)acrylic acid ester with a compound having one unsaturated group and at least one carboxyl group in one molecule, but is not limited thereto. Examples of (meth)acrylic acid esters constituting the copolymerization resin (a) include: (meth)acrylic acid alkyl esters, such as methyl(meth)acrylate, ethyl(meth)acrylate, propyl(meth)acrylate, butyl(meth)acrylate, pentyl(meth)acrylate, and hexyl(meth)acrylate; (meth)acrylic acid esters containing hydroxyl groups, such as 2-hydroxyethyl(meth)acrylate, hydroxypropyl(meth)acrylate, hydroxybutyl(meth)acrylate, and caprolactone-modified 2-hydroxyethyl(meth)acrylate; and glycol-modified (meth)acrylates, such as methoxydiethylene glycol(meth)acrylate, ethoxy di ethylene glycol(meth)acrylate, isooctyloxyethylene glycol(meth)acrylate, phenoxy triethylene glycol(meth)acrylate, methoxytriethylene glycol(meth)acrylate, and methoxypolyethylene glycol(meth)acrylate. These may be used alone or in combination of two or more. Herein, (meth)acrylate is a generic term for acrylates and meth acrylates, and the same applies to other similar expressions.

In addition, examples of the compound having one unsaturated group and at least one carboxyl group in one molecule may include: acrylic acid; methacrylic acid; a modified unsaturated monocarboxylic acid having a chain extended between an unsaturated group and a carboxylic acid, for example, unsaturated monocarboxylic acids with ester bonds by β-carboxyethyl (meth)acrylate, 2-acryloyloxyethyl succinic acid, 2-acryloyloxyethyl hexahydrophthalic acid, lactone modification, or the like; modified unsaturated monocarboxylic acid having an ether bond; and those containing two or more carboxyl groups such as maleic acid in the molecule, and the like. These may be used alone or in combination of two or more.

The compound having an oxirane ring and an ethylenically unsaturated group in one molecule (b) may be any compound having an ethylenically unsaturated group and an oxirane ring in one molecule, and examples thereof may include glycidyl(meth)acrylate, α-methylglycidyl(meth)acrylate, 3,4-epoxy cyclohexylmethyl(meth)acrylate, 3,4-epoxycyclohexylethyl (meth)acrylate, 3,4-epoxycyclohexylbutyl(meth)acrylate, 3,4-epoxycyclohexyl methylaminoacrylate, and the like. These may be used alone or in combination of two or more. For example, the compound having an oxirane ring and an ethylenically unsaturated group in one molecule (b) may be 3,4-epoxycyclohexylmethyl(meth)acrylate.

For example, the resin (A) may have an acid value of 30 to 200 mgKOH/g. When the acid value of the resin (A) is 30 mgKOH/g or higher, an unexposed portion of a coating film of the solder resist composition can be easily removed in an aqueous weak alkali solution. When the acid value of the resin (A) is 200 mgKOH/g or lower, the water resistance and electric characteristics of a cured film can be enhanced.

For example, the weight average molecular weight of the resin (A) may be 5,000 to 100,000 g/mol. When the weight average molecular weight of the resin (A) is 5,000 g/mol or more, the deterioration in the dryness to touch of a coating film of the solder resist composition can be suppressed. When the weight average molecular weight of the resin (A) is 100,000 g/mol or less, the deterioration in developability and storage stability of the solder resist composition can be suppressed.

The content of the resin (A) in the photosensitive resin composition of the present disclosure may be 5 to 40 wt %, 10 to 35 wt %, or 12 to 33 wt %, relative to the total weight of the resin composition. The composition includes a solid and a solvent. The content of the resin (A) may be calculated on the basis of solid content conversion.

When the content of the resin (A) is within the above range, excellent yellowing resistance and high reflectance can be attained, and a coating film of the solder resist can be favorably formed, superb pencil hardness and adhesion can be exhibited, and the decrease in dry to touch and undercut of a coating film can be suppressed.

### [(B) Inorganic Filler]

The photosensitive resin composition according to an aspect of the present disclosure can obtain high reflectance by including an inorganic filler.

Examples of the inorganic filler may include titanium oxide, zinc oxide, basic carbonates, basic sulfates, sulfates, zinc sulfide, antimony oxide, aluminum hydroxide, silica, barium sulfate, and the like. For example, when the composition is prepared by using a mixture of barium sulfate and silica as an inorganic filler, the L value is 80 or more, the a value is −5 or more, and the b value is −5 or more. The L value may be measured by Hunter 1948. For example, when the composition is prepared by using a mixture of a high content of titanium oxide and silica as an inorganic filler, a cured product of the composition has an L value of 90 or more, an a value of −3 or more, and a b value of −3 or more, showing high whiteness and reflectance. For example, when the composition is prepared by using at least one of titanium oxide or silica as an inorganic filler, the L value is 95 or more, the a value is −2 or more, and the b value is −1 or more, showing the highest whiteness and reflectance.

For example, a method for preparing titanium oxide may be any one of a sulfuric acid method or a chlorine method, and may be preferably a chlorine method. For example, sulfuric acid may not be used in the preparation process. The surface treatment of the titanium oxide is not particularly limited, but during neutralization, titanium oxide may be acid-treated with hydrochloric acid, nitric acid, phosphoric acid, acetic acid, or the like, other than sulfuric acid.

The titanium oxide may be any titanium oxide having any structure among a rutile type, an anatase type, and a ramsdellite type, which may be used alone or in combination of two or more. Among these, the ramsdellite-type titanium oxide may be obtained by performing chemical lithium oxide desorption treatment on ramsdellite-type Li_{0.5}TiO₂.

Among these, the use of the rutile-type titanium oxide can further enhance heat resistance, minimize the discoloration due to light irradiation, and prevent the deterioration in quality even in a strict use environment. In particular, heat resistance can be improved by using rutile-type titanium oxide that has been surface treated with aluminum oxide such as alumina. The content of rutile-type titanium oxide surface-treated with aluminum oxide in the total titanium oxide is for example 35 mass % or more, for example 55 mass % or more, with an upper limit of 100 mass % or less, that is, the entirety of the titanium oxide may be rutile-type titanium oxide surface treated with the aluminum oxide. In addition, anatase-type titanium oxide has a lower hardness than rutile titanium oxide, and thus the use of anatase-type titanium oxide is preferable in terms of moldability of a composition.

In the photosensitive resin composition of the present disclosure, the mixing amount of the inorganic filler (B) may be in the range of 30 to 70 mass %, for example, in the range of 40 to 70 mass %, and for example, in the range of 45 to 70 mass %, relative to the total resin composition. The content of the inorganic filler (B) may be calculated on the basis of solid content conversion. A content of the inorganic filler (B) within the above range is advantageous for high reflection, while a content smaller than the above range results in a reduction in reflectance, and a content exceeding the above range may cause cracking.

In the inorganic filler (B), the titanium oxide has a sulfur concentration of 100 ppm or less, or 50 ppm or less. Additionally, a commercially available titanium oxide having a sulfur concentration of 100 ppm or less may be used, or a commercially available titanium oxide having a sulfur concentration of 100 ppm or more may be heat-treated, chemically treated, or refined by washing, firing, or the like, to reduce the sulfur concentration before mixing. Particularly, the sulfur included in the titanium oxide refers to all sulfur detected by analysis. Such a sulfur encompasses sulfur adsorbed on titanium oxide and sulfur applied as impurities to titanium oxide. Additionally, the titanium oxide may have a sodium concentration of 100 ppm or less, or 50 ppm or less. A lower sodium concentration may be more preferable. A too high sodium concentration may accelerate the corrosion or oxidation of a copper substrate when exposed to moisture due to sodium ions. For this reason, the concentration of sodium ions may be 100 ppm or less.

Additionally, the photosensitive resin composition of the present disclosure may include titanium oxide with a sulfur concentration of 100 ppm or more as long as the advantages of the present disclosure are not impaired. Examples of the titanium oxide having a sulfur concentration of 100 ppm or more may include CR-58, CR-90, and R-630 by ISHIHARA Co. Ltd., R-21 by Sakai-Chem Co. Ltd., and the like.

Alternatively, T-550, T-580, R-630, R-820, CR-50, CR-60, R-90, or CR-97 by ISHIHARA SANGYO Co. Ltd., Ti PURE R-706, R-902+, or R931 by DuPont Co. Ltd., TR-600, TR-700, or TR-840 by Fuji Titanium Industries Co. Ltd., or KR-270, KR-310, and KR-380 by Titanium Industries Co. Ltd., which are rutile-type chlorine-based titanium oxides, may be used.

When the particle size of titanium oxide is too small, fluidity may deteriorate, whereas when the particle size is too large, the insertability into a small diameter of a substrate may deteriorate. Considering these, the median particle size of titanium oxide may be in the range of 0.1 to 5 μm, for example, in the range of 0.1 to 1 μm, for example, in the range of 0.1 to 0.5 μm, and may be 0.36 μm. When the particle size of titanium oxide is within the above range, a high reflectance can be exhibited. The above particle size was measured using a laser diffraction method.

Among the inorganic fillers (B), examples of the barium sulfate may include precipitated barium sulfate #100, precipitated barium sulfate #300, precipitated barium sulfate SS-50, BARIACE B-30, BARIACE B-31, BARIACE B-32, BARIACE B-33, BARIACE B-34, BARIFINE BF-1, BARIFINE BF-10, BARIFINE BF-20, BARIFINE BF-40 (Sakai Chemical Industry Co. Ltd.), W-1, W-6, W-10, C300 (Takehara Kagaku Kogyo Co. Ltd.), and the like.

Among the inorganic fillers (B), the silica particles are not particularly limited, and may be obtained by a method known to a person skilled in the art. For example, the silica particles may be manufactured by combusting a silicon powder through a vaporized metal combustion (VMC) method. According to the VMC method, oxide particles are obtained by forming a chemical flame by a burner in an atmosphere containing oxygen, injecting a metal powder constituting a part of target oxide particles in the chemical flame at an amount sufficient to form dust cloud, and causing knocking. Examples of commercially available silica include SO series made by Admatechs, HPS series (HPS-0500, HPS-1000, HPS3500, etc.) made by Toagosei, and the like.

### [(C) Mercapto-Modified (Meth)Acrylate]

The photosensitive resin composition according to an aspect of the present disclosure ensures enhanced surface curing by using the mercapto-modified acrylate (C), thereby achieving improved gloss and high reflectance.

Furthermore, the use of the mercapto-modified acrylate (C) of the present disclosure together with the above-described inorganic filler (B) for the photosensitive resin composition can enhance the surface curing of a photosensitive resin layer, thereby implementing higher reflectance and higher gloss through the enhanced surface curing.

The mercapto-modified acrylate (C) of the present disclosure is a compound modified by the introduction of a mercapto group among acrylate compounds, and the acrylate compounds may be mono- or poly-functional acrylate compounds, or aliphatic compounds of 1 to 15 carbon atoms substituted with at least one functional group selected from the group consisting of an acryloyl group, an acryloyloxy group, and an acryloyloxyalkyl groups, or may be for example pentanetriacrylate or the like.

The mercapto-modified acrylate (C) of the present disclosure may be curable or active energy ray-curable. The mercapto-modified (meth)acrylate (C) of the present disclosure may be obtained by a Michael addition reaction of a polyfunctional thiol compound and a stoichiometrically excessive difunctional or more polyfunctional (meth)acrylate compound. Examples of the polyfunctional thiol compound include: a poly-functional thiol compound in a reaction product of a polyisocyanate, such as pentaerythritol tetrakis(3-mercaptopropionate) (molecular weight: 489 g/mol), trimethylolpropane tris(3-mercaptopropionate) (molecular weight: 399 g/mol), or 1,3-bis(2-isocyanato-2-propyl) benzenetetrathiol, and a poly-functional thiol compound, such as trimethylolpropane tris(3-mercaptopropionate); a poly-functional thiol compound in a reaction product of a polyisocyanate, such as isophorone diisocyanate, and a poly-functional thiol compound, such as trimethylolpropane tris(3-mercaptopropionate); a poly-functional thiol compound in a reaction product of a polyisocyanate, such as hexamethylene diisocyanate, and a poly-functional thiol compound, such as trimethylolpropane tris(3-mercaptopropionate); 1,6-hexanedithiol (molecular weight: 150 g/mol), ethylene glycol di-2-mercaptoacetate (molecular weight: 210 g/mol), pentaerythritol tetrakis(2-mercaptoacetate) (molecular weight: 433 g/mol), trimethylolpropane tris(2-mercaptoacetate), ethylene glycol bis(3-mercaptopropionate) (molecular weight: 238 g/mol), and the like. For example, the mercapto-modified acrylate (C) may have two or more mercapto groups or three or more mercapto groups.

The mercapto-modified acrylate (C) may have a weight average molecular weight of 5,000 g/mol or less, 3,000 g/mol or less, or 2,000 g/mol or less. In a weight average molecular weight of 5,000 g/mol or less, the mobility of the mercapto-modified (meth)acrylate molecules is lowered, thereby suppressing the deterioration in the reactivity of the formation of the active energy ray-curable coating film of the present disclosure. For example, when a coating film is cured with UV-LED under the deterioration in reactivity, the tackiness of the surface of the cured coating film is increased, and the cured coating film is likely to adhere to a printed material when the printed material is put on the cured coating film.

In the photosensitive resin composition of the present disclosure, the content of the mercapto-modified (meth)acrylate may be 1-20 parts by weight, 1-10 parts by weight, or 1-7 parts by weight relative to a total of 100 parts by weight of the composition.

When the content of the mercapto-modified acrylate (C) is within the above range, the enhancement in surface curing, improvement in gloss, and high reflectance can be achieved, and even after the manufacturing process, a smaller reduction in reflectance and excellent crack resistance can be achieved. Furthermore, the deterioration in gloss caused by the deterioration in surface curing can be suppressed, high reflectance can be attained, and the breakage of a coating can be reduced through appropriate surface curing, and the resolution can be increased.

### [(D) Resin Containing Aromatic Ring]

The photosensitive resin composition of the present disclosure may include the carboxyl group-containing resin not containing an aromatic ring (A), and may further include (D) a resin containing an aromatic ring in addition to the resin (A).

The resin containing an aromatic ring (D) can exhibit excellent resistance to yellowing through a combination with the resin (A). The photosensitive resin composition according to an aspect of the present disclosure can exhibit excellent yellowing resistance by including the resin containing an aromatic ring (D) in a smaller content than the resin (A).

The resin containing an aromatic ring (D) of the present disclosure may be cured by, for example, heating to exhibit electrical insulation.

Examples of the aromatic ring may include a benzene ring, a pyridine ring, a pyrimidine ring, a triazine ring, and the like. Examples of the resin containing an aromatic ring (D) of the present disclosure may include a melamine resin, a silicone resin, a resin having a styrene backbone. For example, a resin having a styrene backbone may be used.

The resin containing an aromatic ring (D) may contain a carboxyl group, and for example, may be a carboxyl group-containing resin having a styrene backbone. For example, the resin containing an aromatic ring (D) may employ a mixture of a carboxyl group-containing resin having a styrene backbone and a carboxyl group-containing resin other than the carboxyl group-containing resin having a styrene backbone.

For example, when the resin containing an aromatic ring (D) is a carboxyl group-containing resin having a styrene backbone, such a resin does not have a photosensitive group, such as an ethylenically unsaturated bond having a carboxyl group in the molecule, while having a styrene backbone in the molecule, an average molecular weight of 10,000 to 50,000 g/mol, and an acid value of 80 to 200 mgKOH/g. This carboxyl group-containing resin having a styrene backbone may be synthesized by copolymerization using styrene as an essential monomer. By utilizing a carboxyl group-containing resin with properties of the above-described ranges, a cured coating film comprising the photosensitive resin composition of the present disclosure has excellent dryness to touch and anti-flow effects.

The carboxyl group-containing resin having a styrene backbone may be for example a carboxyl group-containing resin (any of an oligomer and a polymer) that can be obtained by copolymerization of an unsaturated carboxylic acid, such as (meth)acrylic acid, with a compound containing an unsaturated group selected from styrene, α-methylstyrene, low-grade alkyl (meth)acrylates, isobutylene, and the like. Particularly, the lower alkyl may refer to an alkyl group of 1 to 5 carbon atoms.

In the photosensitive resin composition of the present disclosure, the average molecular weight per weight of the carboxyl group-containing resin having a styrene backbone varies depending on the backbone of the resin, but may be 10,000 g/mol to 50,000 g/mol, 10,000 g/mol to 25,000 g/mol, 10,000 g/mol to 20,000 g/mol, or 10,000 g/mol to 17,000 g/mol. A weight average molecular weight of 10,000 g/mol or more can improve the anti-flow effect and dryness to touch (tackiness), enhance the moisture resistance of an exposed coating, suppress the thinning of the film during development, and suppress the deterioration in resolution. Additionally, a weight average molecular weight of 50,000 g/mol or less can improve the anti-flow effect, developability, and storage stability.

In the photosensitive resin composition of the present disclosure, the acid value of the carboxyl group-containing resin may be 80 to 200 mgKOH/g or 100 to 180 mgKOH/g. When the acid value of the carboxyl group-containing resin having a styrene backbone is 80 mgKOH/g or more, the softening point can be increased, resulting in improved tackiness and developability. When the acid value of the carboxyl group-containing resin having a styrene backbone is 200 mgKOH/g or less, the stress does not occur through an appropriate crosslinking density during curing, and a favorable coating film can be obtained.

In the photosensitive resin composition of the present disclosure, the carboxyl group-containing resin having a styrene backbone, despite having an aromatic ring, can suppress the discoloration and the reduction in reflectance in a cured product under light irradiation or heat, and exhibit excellent developability and dryness to touch, due to the styrene backbone. The proportion of the styrene backbone may be 10 to 80 mol %, 10 to 60 mol %, or 10 to 50 mol % in the molecule. That is, 30 to 60 mol % of styrene may be used relative to the total amount of monomers when a carboxyl group-containing resin having a styrene backbone is synthesized. When the proportion of the styrene backbone of the carboxyl group-containing resin is 10 mol % or more in the molecule, improved compatibility with other components can be obtained, and when the proportion is 80 mol % or less in the molecule, favorable developability can be obtained.

The carboxyl group-containing resin having a styrene backbone may be prepared by suspension to achieve a high molecular weight. Consequently, the photosensitive resin composition using the corresponding resin may have an excellent dryness to touch (tackiness). In general, the carboxyl group-containing resin having a styrene backbone, when prepared by suspension polymerization, has a high molecular weight, but considering characteristics, such as screen printing compatibility, dryness to touch, and developability, the weight average molecular weight of the resin may be restricted to a range of 10,000 to 50,000 g/mol. Therefore, for the control of the molecular weight, a chain transfer agent may be used in the synthesis of a carboxyl group-containing resin having a styrene backbone.

In addition, for the acceleration of polymerization, a polymerization initiator may be used in synthesis of a carboxyl group-containing resin having a styrene backbone. Examples of the polymerization initiator include benzoyl peroxide (BPO), t-butylperoxy-2-ethylhexanoate, 2,2′-azo bis(2-methylbutyronitrile) (AMBN), and the like, and the polymerization inhibitor may be benzoyl peroxide (BPO). The mixing amount of the polymerization initiator may be 0.1 to 10 wt % or 0.1 to 6 wt % in terms of the solid content, relative to 100 wt % of the carboxyl group-containing resin having a styrene backbone.

In the photosensitive resin composition of the present disclosure, the content of the resin containing an aromatic ring (D) may be 0.1 to 15 wt %, 1 to 10 wt %, or 2 to 6 wt %, relative to the total weight of the composition. The photosensitive resin composition includes a solid and a solvent.

When the content of the resin containing an aromatic ring (D) is within the above range, the discoloration and the reduction in reflectance are suppressed and the developability and dryness to touch are excellent, so that the effects of improving the reflectance and preventing yellowing can be further enhanced.

### [(E) Photopolymerization Initiator]

The photosensitive resin composition according to an aspect of the present disclosure may include (E) a photopolymerization initiator of a trimethylbenzoyl phosphine oxide group-including compound having at least one P—O band (hereinafter, “photopolymerization initiator (E)”).

In 2,4,6-trimethylbenzoyldiphenyl phosphine oxide (TPO) or the like widely used as a conventional photopolymerization initiator, a significant amount of outgas is generated during the curing process, and such outgas diffused into a silicone encapsulant layer or a protective film, thereby yellowing the silicone encapsulant, thus reducing the reflectance and hindering curing of the silicone encapsulant. The products have issues with their long-term reliability.

A trimethylbenzoyl phosphine oxide group-containing polymer as a photopolymerization initiator, which is a high molecular structure, has a large molecular weight, and thus the amount of outgas generated due to heat is small even in the final curing step, reflow, and sintering processes using heat.

Meanwhile, even compounds containing trimethylbenzoyl phosphine oxide having a lower molecular weight compared with TPO contain one or more P—O bonds, leading to an enhancement in intermolecular bonding (e.g., stronger hydrogen bonding with OH or COOH groups remaining in the composition without reacting), thereby significantly inhibiting the outgassing of the photopolymerization initiators.

For example, the trimethylbenzoyl phosphine oxide group-containing compound may include three or more hydrogen-bondable sites. This can enhance the intermolecular bonding force, thereby significantly suppressing the outgassing of the photopolymerization initiator.

Consequently, this can solve the yellowing and non-curing of the silicone encapsulant, reducing the amount of outgas of the photopolymerization initiator transferred to the protective film, and significantly increasing the reaction rate of the silicone encapsulant.

In the case of using a photopolymerization initiator, such as TPO, a separate firing process (for example, curing at 150 °C for 6 hours) was added after the reflow process to efficiently remove the resultant outgas, but this firing process caused a significant reduction in reflectance, resulting in an increase in power consumption when the chip was mounted.

However, the use of the above-described photopolymerization initiator (E) of the present disclosure can omit the firing process to reduce the working time, thus increasing the yield, reduce costs, increase the reflectance, prevent the power consumption due to a reduction in reflectance, minimize the content of outgas of the photopolymerization initiator even without a protective film for the removal of the photopolymerization initiator, significantly increase the curing degree of silicone, improve the long-term reliability, and exhibit excellent HAST resistance and reflectance after HAST testing. Additionally, the reduction in reflectance under high temperature/high humidity conditions can be suppressed.

The photopolymerization initiator (E) may be a liquid at room temperature (20 °C) and 1 atm.

The photopolymerization initiator (E) may have a P—O bond.

The photopolymerization initiator (E) may include a *—C(═O)—P(═O)R₁—O—*′ moiety (where, R₁ is an alkyl group of 1 to 20 carbon atoms, an alkenyl group of 2 to 20 carbon atoms, an alkynyl group of 2 to 20 carbon atoms, or a cyclic group of 5 to 20 carbon atoms).

When the photopolymerization initiator (E) is a trimethylbenzoyl phosphine oxide group-containing polymer, the weight average molecular weight (Mₙ) of the trimethylbenzoyl phosphine oxide group-containing polymer may be about 1,000 g/mol or more. For example, the trimethylbenzoyl phosphine oxide group-containing polymer may have a weight average molecular weight (Mₙ) of 1,000 g/mol to 100,000 g/mol.

The trimethylbenzoyl phosphine oxide group-containing polymer may be represented by Chemical Formula 1 below.

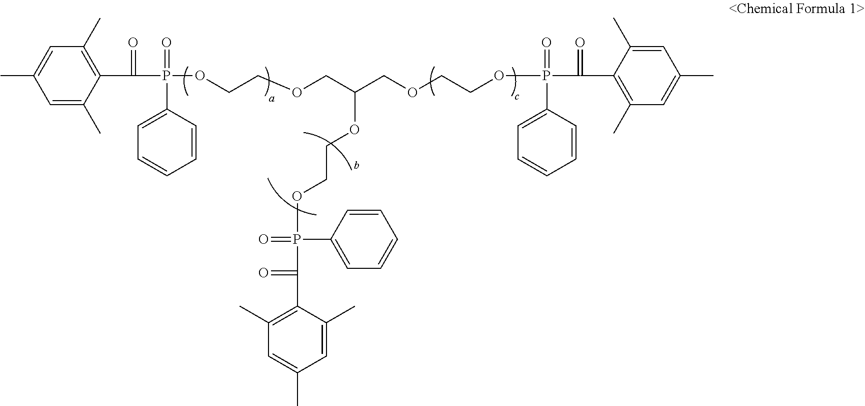

a=0 to 100, b=0 to 100, and c=0 to 100

When the photopolymerization initiator (E) is a trimethylbenzoyl phosphine oxide group-containing compound having a P—O band, the trimethylbenzoyl phosphine oxide group-containing compound having a P—O band may include an alkoxy group.

For example, a+b+c>0 in Chemical Formula 1.

For example, the trimethylbenzoyl phosphine oxide group-containing compound having a P—O band may include an ethoxy group.

The trimethylbenzoyl phosphine oxide group-containing polymer having a P—O band may be represented by Chemical Formula 2 below.

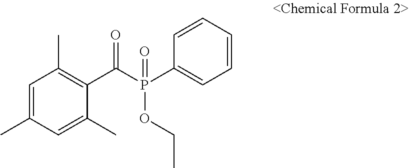 [SMILES: CCOP(=O)(C(=O)c1c(C)cc(C)cc1C)c1ccccc1]

For example, the photopolymerization initiator (E) may further include at least one selected from the group consisting of benzoin and its alkyl ethers, acetophenones, anthraquinones, thioxanthone, ketals, benzophenones, α-aminoacetophenones, acylphosphine oxides, acylphosphinates, and oxime esters.

In the photosensitive resin composition of the present disclosure, the content of the photopolymerization initiator (E) may be 0.01 to 10 wt %, 0.01 to 7 wt %, or 0.01 to 5 wt %, relative to the total composition. The photopolymerization initiator (E) included within the above range results in sufficient photo-curability on copper, leading to favorable coating film curability, improved coating film characteristics, such as chemical resistance, and improved deep curability.

A content of the photopolymerization initiator (E) within the above range results in a gentle undercut and an insignificant enlargement of the upper part (halation), leading to excellent resolution and a large number of solder resist openings. Additionally, a high reflectance can be maintained.

### [(F) Silane Coupling Agent]

The photosensitive resin composition according to an aspect of the present disclosure may further include (F) a silane coupling agent. The photosensitive resin composition can exhibit improved crack resistance, increased reflectance compared with existing ones, and excellent gloss, by including the silane coupling agent (F).

The silane coupling agent (F) of the present disclosure may have an organic group, such as a vinyl group, a styryl group, an acryl group, a methacryl group, an isocyanurate group, an acid anhydride group, a ureide group, an epoxy group, an amino group, a methacryloxy group, a mercapto group, an isocyanate group, or an isocyanurate group.

Examples of the silane coupling agent having a vinyl group may include vinyltrimethoxysilane, vinyltriethoxysilane, and the like. Examples of the silane coupling agent having a styryl group may include p-styryl methoxysilane and the like. Examples of the silane coupling agent having a methacrylic group may include 3-methacryloxypropylmethyldimethoxysilane, 3-methacryloxypropyltrimethoxy silane, 3-methacryloxypropyldiethoxysilane, 3-methacryloxypropyltriethoxysilane, and the like. Examples of the silane coupling agent having an acrylic group may include 3-acryloxypropyl trimethoxysilane and the like. Examples of the silane coupling agent having an amino group may include N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxy-silyl-N-(1,3-dimethyl-butylidene)propylamine, N-phenyl-3-aminopropyl trimethoxysilane, N-(vinylbenzyl)-2-aminoethyl-3-aminopropyltrimethoxysilane, and the like. Examples of the silane coupling agent having a methylcryloxy group may include 3-methacryloxypropyltrimethoxysilane, 3-methacryloxypropyltriethoxysilane, and the like. Examples of the silane coupling agent having a mercapto group may include 3-mercaptopropylmethyldimethoxysilane, 3-mercaptopropyltrimethoxysilane, and the like. Examples of the silane coupling agent having an isocyanate group may include 3-isocyanate propyltriethoxysilane and the like. Examples of the silane coupling agent having an isocyanurate group may include tris-(trimethoxysilylpropyl)isocyanurate. Examples of the silane coupling agent having a ureide group may include 3-ureidopropyltrialkoxysilane and the like. Examples of the silane coupling agent having an acid anhydride group may include 3-(trimethoxysilyl)propylsuccinic anhydride and the like.

The silane coupling agent may be a silane coupling agent having an epoxy group, and examples thereof may include 2-(3,4-epoxycyclohexyl) ethyltrimethoxysilane, 3-glycidoxypropylmethyldi methoxysilane, 3-glycidoxypropyltrimethoxysilane, 3-glycidoxypropylmethyldiethoxysilane, and 3-glycidoxypropyltriethoxysilane, and for example, may be 3-glycidoxypropyltriethoxysilane.

In the photosensitive resin composition of the present disclosure, the content of the silane coupling agent (F) may be 0.1 to 5 wt %, 0.3 to 3 wt %, or 0.4 to 2 wt %, relative to the total composition. The composition includes a solid and a solvent.

When the content of the silane coupling agent (E) is within the above range, the composition has excellent crack resistance, high reflectance, superb adhesion, and low tackiness, and thus can be suitable for film formation.

The silane coupling agent (F) may be a commercially available product, and examples thereof may include KBM-1003, KBE-1003, KBM-303, KBM-402, KBM-403, KBE-402, KBE-403, KBM-1403, KBM-502, KBM-503, KBE-502, KBE-503, KBM5103, KBM-602, KBM-603, KBM-903, KBE-903, KBE-9103P, KBM-573, KBM-575, KBM-9659, KBM-585A, KBM-802, KBM-803, KBE-9007N, X-12-967C, and the like by Shin-Etsu Kagaku Kogyo.

### [(G) Resin Having Urethane Bond]

The photosensitive resin composition according to an aspect of the present disclosure may further include (G) a resin having a urethane bond. The resin having a urethane bond (G) may have excellent flexibility.

The photosensitive resin composition is not broken even on a flexible substrate or a thin plate with a small thickness, allows for lamination to a uniform thickness, and has excellent resistance to cracking or breaking when undergoing external impacts or bending, by employing the resin having a urethane bond (G).

The resin having a urethane bond (G) of the present disclosure may include a modified urethane resin, and examples of the resin having a urethane bond may include ester type urethanes, ether type urethanes, modified urethane acrylates, modified urethane epoxy, silicone modified urethanes, or fluorine type modified urethanes, and the like, and for example may be a modified urethane epoxy acrylate containing an epoxy group.

The resin having a urethane bond (G) of the present disclosure may employ a known compound having a urethane bond. Examples thereof may include reaction products of isocyanate compounds (e.g., mono isocyanate, diisocyanate, and polyisocyanate) with compounds having an OH group (e.g., a monohydric alcohol, a polyhydric alcohol such as a polyester polyol or a polyether polyol, and epoxy (meth)acrylates), or modifications thereof.

The resin having a urethane bond (G) of the present disclosure may have a carboxyl group, an epoxy group, or a (meth)acryloyl group, and examples thereof may include (1) carboxyl group-containing resins, (2) epoxy group-containing resins, (3), (4), (5) (meth)acryloyl group-containing resins, and the like:
(1) a carboxyl group-containing photosensitive polyurethane resin by a poly-addition reaction of a carboxyl group-containing dialcohol compound, a diol compound, and a reaction product of diisocyanate and a monocarboxylic acid compound having an ethylenically unsaturated double bond, such as a bifunctional epoxy resin (meth)acrylate, for example, a bisphenol A epoxy resin, a hydrogenated bisphenol A epoxy resin, a bisphenol F epoxy resin, a bisphenol S epoxy resin, a bixylenol epoxy resin, or a phenolic epoxy resin, a partial anhydride thereof, or a modification thereof;
(2) a urethane-modified epoxy resin having a urethane bond and two or more epoxy moieties in the molecule, obtained by reacting a hydroxyl group-containing epoxy compound with a urethane bond-containing compound having an isocyanate group obtained by reacting a polyhydroxy compound and a polyisocyanate compound;
(3) a urethane resin by a poly-addition reaction of a diisocyanate, such as an aliphatic diisocyanate, a branched chain diisocyanate, an alicyclic diisocyanate, or an aromatic diisocyanate, and a diol compound, such as a polycarbonate-based polyol, a polyether-based polyol, a polyester-based polyol, a polyolefin polyol, an acryl polyol, an epoxy resin having a hydroxyl group (which can be used to obtain a urethane resin having an epoxy group), a bisphenol A alkylene oxide adduct diol, a compound having a phenolic hydroxyl group and an alcoholic hydroxyl group;
(4) a photosensitive polyurethane resin obtained by a poly-addition reaction of the isocyanate and the diol compound, wherein part or all of the diisocyanate in (3) above is replaced with a reaction product of isophorone diisocyanate and pentaerythritol triacrylate, and/or a compound having one isocyanate group and one or more (meth)acryloyl groups in the molecule; and
(5) a terminal (meth)acrylated photosensitive polyurethane resin prepared by adding a compound having one hydroxyl group and one or more (meth)acryloyl groups in a molecule, such as a hydroxyalkyl(meth)acrylate, during the synthesis of one of the resins (3) and (4).

Also, as above, one resin may have at least two types of a carboxyl group, an epoxy group, or a methacryloyl group.

The resin having a urethane bond (G) may be (1) among carboxyl group-containing resins, (2) among epoxy group-containing resins, and (5) among (meth)acryloyl group-containing resins.

The diisocyanate may be, for example, an aromatic polyisocyanate, an aliphatic polyisocyanate, or an alicyclic polyisocyanate. Examples of the aromatic polyisocyanate may include 4,4′-diphenylmethane diisocyanate, 2,4-diisocyanate-2,6-tolylene diisocyanate, naphthalene-1,5-diisocyanate-o-xylene diisocyanate, m-xylene diisocyanate, 2,4-triene dimer, and the like. Examples of the aliphatic polyisocyanate may include tetramethylene diisocyanate, hexamethylene diisocyanate, methylene diisocyanate, trimethylhexamethylene diisocyanate, 4,4-methylenebis (cyclohexyl isocyanate), and isophorone diisocyanate. Examples of the alicyclic polyisocyanate may include bicycloheptane triisocyanate. For example, the diisocyanate may be an aliphatic isocyanate.

When the resin having a urethane bond (G) is a carboxyl group-containing resin having a urethane bond, the acid value of the carboxyl group-containing resin may be 40 to 200 mgKOH/g or 45 to 120 mgKOH/g. When the acid value of the carboxyl group-containing resin is in the range of 40 to 200 mgKOH/g, the adhesion of a cured film is ensured to facilitate alkali development, and thus the dissolution of an exposed area by a developing solution is suppressed, so that lines are not narrowed more than necessary, allowing for the easy drawing of normal resist patterns.

When the resin having a urethane bond (G) is a carboxyl group-containing resin having a urethane bond, the weight average molecular weight of the carboxyl group-containing resin varies depending on the backbone of a resin, but may be 2,000 to 150,000 g/mol, 5,000 to 50,000 g/mol, or 2,000 to 50,000 g/mol. A weight average molecular weight of the carboxyl group-containing resin within the above range results in favorable tackiness, thereby improving the moisture resistance of a cured film and reducing the thinning of a coating film during development. Furthermore, a weight average molecular weight within the above range can lead to favorable resolution and developability and improved storage stability.

Exemplary commercially available products of the resin having a urethane bond (G) (e.g., a carboxyl group-containing resin having a urethane bond) may include UXE-3000 (Japan Explosives Co., Ltd.), EPU-7N (urethane modified epoxy resin; ADEKA Co., Ltd.), and Ebecryl 210 (aromatic urethane acrylate; Daicel Allnex Co., Ltd.).

In the photosensitive resin composition of the present disclosure, the content of the resin having a urethane bond (G) may be 0.1 to 15 wt %, 5 to 13 wt %, or 8 to 12 wt %, relative to the total composition. The composition includes a solid and a solvent. When the content of the resin having a urethane bond (G) is within the above range, the composition can exhibit excellent flexibility and crack resistance, appropriate tackiness, and superb printability and drying properties.

In the photosensitive resin composition of the present disclosure, the weight average molecular weight of the resin having a urethane bond (G) may be 2,000 to 150,000 g/mol or 2,000 to 50,000 g/mol. When the weight average molecular weight of the resin having a urethane bond (G) is within the above range, the composition can exhibit excellent crack resistance and flexibility.

### [Other Optional Components]

If necessary, various additives as optional components may be added to the photosensitive resin composition of the present disclosure. Specifically, a heat curing catalyst, a dispersant, an antioxidant, a colorant, an epoxy resin, an oxetane compound, a (meth)acrylic resin, and various other additives, or a mixture of two or more of these may be added. One or more of the following materials may be included as the optional components.

### <Epoxy Resin>

The epoxy resin of the present disclosure may employ a well-known and commonly used compound having one or more epoxy groups. For example, the epoxy resin may not overlap the components (A) to (G) described above. For example, the epoxy resin may be a compound having two or more epoxy groups. Examples of the epoxy resin may include a monoepoxy compound, such as butyl glycidyl ether, phenyl glycidyl ether, or glycidyl (meth)acrylate, and a compound having two or more epoxy groups in one molecule, such as a bisphenol A epoxy resin, a bisphenol S epoxy resin, a bisphenol F epoxy resin, a phenol novolac type epoxy resin, a cresol novolac type epoxy resin, an aliphatic ring epoxy resin, trimethylolpropane polyglycidyl ether, phenyl-1,3-diglycidyl ether, biphenyl-4,4′-diglycidyl ether, 1,6-hexanediol diglycidyl ether, diglycidyl ether of ethylene glycol or propylene glycol, sorbitol polyglycidyl ether, tris(2,3-epoxypropyl)isocyanurate, or triglycidyl tris(2-hydroxyethyl)isocyanurate. These may be used alone or in a combination of two or more according to the required characteristics.

Examples of the compound having two or more epoxy groups include: bisphenol A epoxy resins, such as jER828, jER834, jER1001, and jER1004 by Mitsubishi Chemical Co., Ltd., EPICLON 840, EPICLON 850, EPICLON 1050, and EPICLON 2055 by DIC Co., Ltd., Epototo D-011, YD-013, YD127, and YD-128 by Nittetsu Chemical & Materials Co., Ltd., D.E.R.317, D.E.R.331, D.E.R.661, and D.E.R.664 by Dow Chemical Japan Co., Ltd., Sumi Epoxy ESA-011, ESA-014, ELA-115, and ELA128 by Sumitomo Chemical Co., Ltd., and A.E.R.330, A.E.R.331, A.E.R.661, and A.E.R.664 by Asahi Kasei Materials Co., Ltd. (all trade names); brominated epoxy resins, such as jERYL903 by Mitsubishi Chemical Co., Ltd., EPICLON 152 and EPICLON 165 by DIC Co., Ltd., Epototo YDE-400 and YDE-500 by Nittetsu Chemical & Materials Co., Ltd., D.E.R.542 by Dow Chemical Japan Co., Ltd., Sumitoepoxy ESB-400 and ESB-700 by Sumitomo Chemical Co., Ltd., and A.E.R.711 and A.E.R.714 by Asahi Kasei Materials Co., Ltd. (all trade names); novolac epoxy resins, such as jER152 and jER154 by Mitsubishi Chemical Co., Ltd., D.E.N.431 and D.E.N.438 by Dow Chemical Japan Co., Ltd., EPICLON N-730, EPICLON N-770, and EPICLON N-865 by DIC Co., Ltd., Epototo YDC-701 and YDC-704 by Nittetsu Chemical & Materials Co., Ltd., EPPN-201, EPPN-1025, EPPN-1020, EPPN-104S, RE-306, and NC-3000 by Japan Chemical, Co., Ltd., Sumi Epoxy ESCN-195X and ESCN-220 by Sumitomo Chemical Co., Ltd., A.E.R.ECN-235 and ECN-299 by Asahi Kasei Materials Co., Ltd., YDCN-700-2, YDCN-700-3, YDCN-700-5, YDCN-700-7, YDCN-700-10, YDCN-704, and YDCN-704A by Nittetsu Chemical & Materials Co., Ltd., and EPICLON N-680, N-690, N-695 by DIC Co., Ltd. (all trade names); bisphenol F epoxy resins, such as EPICLON 830 by DIC Co., Ltd., jER807 by Mitsumi Chemical Co., Ltd., and Epototo YDF-175 and YDF-2004 by Nittetsu Chemical & Materials Co., Ltd. (all tradenames); hydrogenated bisphenol A epoxy resins, such as Epototo ST-2004, ST-2007, and ST-3000 by Nittetsu Chemical & Materials Co., Ltd. (all trade names); jER 604 by Mitsumi Chemical Co., Ltd.; Ephotouto YH-434 by Nittetsu Chemical & Materials Co., Ltd.; a glycidyl amine-type epoxy resin such as Sumi Epoxy ELM-120 (trade name) by Sumitomo Chemical Co., Ltd.; hydantoin epoxy resins; alicyclic epoxy resins, such as Celloxide 2021 (trade names) by Daicel Co., Ltd.; trihydroxyphenyl methane epoxy resins, such as YL-933 by Mitsubishi Chemical Co., Ltd., and T.E.N., EPPN-501, and EPPN-502 by Dow Chemical Japan Co., Ltd. (all trade names); bixylenolic or biphenolic epoxy resins, such as YL-6056, YX-4000, and YL-6121 by Mitsubishi Chemical Co., Ltd., or mixtures thereof (all trade names); bisphenol S epoxy resins, such as EBPS-200 by Kayaku Co., Ltd., and EPX-30 by ADEKA, EXA-1514 by DIC Co., Ltd. (all trade names); bisphenol A novolac epoxy resins, such as jER 157S (trade name) by Mitsubishi Chemical Co., Ltd.; tetraphenylolethane epoxy resins, such as jER YL-931 (trade names) by Mitsubishi Chemical Co., Ltd.; heterocyclic epoxy resins, such as TEPIC (trade name) by Nissan Chemical Co., Ltd.; diglycidyl phthalate resins such as Brenmer DGT by Niche Oil Co., Ltd.; tetraglycylyl kylenoylethane resins, such as ZX-1063 by Nittetsu Chemical & Materials Co., Ltd.; naphthalene group-containing epoxy resins, such as ESN-190 and ESN-360 by Nittetsu Chemical & Materials Co., Ltd., and HP-4032, EXA-4750, and EXA-4700 by DIC Co., Ltd.; epoxy resins having a dicyclopentadiene backbone, such as HP-7200 and HP-7200H by DIC Co., Ltd.; glycidyl methacrylate copolymer epoxy resins, such as CP-50S and CP-50M by Niche Oil Co., Ltd.; copolymer epoxy resins of cyclohexylmaleimide and glycidyl methacrylate; and CTBN modified epoxy resins (such as YR-102 and YR-450 by Nittetsu Chemical & Materials Co., Ltd.), but are not limited thereto. Among these, the compound having two or more epoxy groups may be a bisphenol A epoxy resin, a heterocyclic epoxy resin, or a mixture thereof rather than a resin having excellent discoloration resistance. These epoxy resins may be used alone or in a mixture of two or more thereof.

In the photosensitive resin composition of the present disclosure, the epoxy resin may be a bisphenol-based epoxy resin, for example, a bisphenol epoxy-based epoxy resin having two or more epoxy groups. The mixing amount of the bisphenol-based epoxy resin having two or more epoxy groups used in the present disclosure may be 1 to 15 wt %, 1 to 10 wt %, or 3 to 10 wt %, relative to the total composition. The composition includes a solid and a solvent.

When the content of the epoxy resin is within the above range, a coating film formed of the composition exhibits excellent adhesion, heat resistance, and pencil hardness, undergoes favorable curing, and can solve problems, such as yellowing and difficulty in achieving high reflectance after processes.

In the photosensitive resin composition of the present disclosure, the weight average molecular weight of the epoxy resin may be 150 to 100,000 g/mol.

### <Oxetane Compound>

Next, an oxetane compound will be described. An oxetane compound containing an oxetane ring is represented by general formula (I) below:

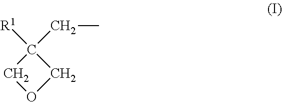

(where R¹ represents a hydrogen atom or an alkyl group of 1 to 6 carbon atoms). Specific examples of the oxetane compound may be include 3-ethyl-3-hydroxymethyloxetane (DongA Synthetic Co., Ltd., trade name: OXT-101), 3-ethyl-3-(phenoxymethyl)oxetane (DongA Synthetic Co., Ltd., trade name: OXT-211), 3-ethyl-3-(2-ethyl hexyloxymethyl)oxetane (DongA Synthetic Co., Ltd., trade name: OXT-212), 1,4-bis {[(3-ethyl-3-ocycetaniru)methoxy]methyl}benzene (DongA Synthetic Co., Ltd., trade name: OXT-121), and bis(3-ethyl-3-oxetanylmethyl)ether (DongA Synthetic Co., Ltd., trade name: OXT-221). Also, examples thereof may include a phenol novolac type oxetane compound. Such oxetane compounds may be used alone or in combination with the epoxy compounds.

### <(Meta)Acrylic Resin>

A (meth)acrylic resin is a photocurable resin. The photocurable resin is not limited as long as the resin is cured by active energy ray irradiation to exhibit electrical insulation, and for example, may be a compound having at least one ethylenically unsaturated bond in the molecule. For example, the (meth)acrylic resin may not overlap the components (A) to (G) described above.

The compound having an ethylenically unsaturated bond may include a photopolymerizable oligomer, a photopolymerizable monomer, and a photopolymerizable vinyl monomer, which are well known and commonly used. The photopolymerizable oligomer may be an unsaturated polyester-based oligomer, a (meth)acrylate-based oligomer, or the like. Examples of the (meth)acrylate-based oligomer may include epoxy (meth)acrylates, such as phenol novolac epoxy (meth)acrylate, cresol novolac epoxy (meth)acrylate, and bisphenol-type epoxy (meth)acrylate, urethane (meth)acrylate, epoxy urethane (meth)acrylate, polyester (meth)acrylate, polyether (meth)acrylate, polybutadiene modified (meth)acrylate, and the like.

As the photopolymerizable monomer or the photopolymerizable vinyl monomer, a well-known and commonly used one may be used, and examples thereof may include: styrene derivatives, such as styrene, chlorostyrene, and α-methylstyrene; vinyl esters, such as vinyl acetate, vinyl butyrate, and vinyl benzoate; ethers, such as vinyl isobutylether, vinyl-n-butylether, vinyl-t-butylether, vinyl-n-amyl ether, vinyl isoamyl ether, vinyl-n-octadecyl ether, vinyl cyclohexyl ether, ethylene glycol monobutylether, and triethylene glycol monomethyl ether; (meth)acrylamides, such as acrylamide, methacrylamide, N-hydroxymethylacrylamide, N-hydroxymethylmethacrylamide, N-methoxymethylacrylamide, N-ethoxymethyl acrylamide, and N-butoxymethylacrylamide; aryl compounds, such as triallyl isocyanurate, diaryl phthalate, and diaryl isophthalate; (meth)acrylic acid esters, such as 2-ethylhexyl(meth)acrylate, lauryl(meth)acrylate, tetrahydrofurfuryl (meth)acrylate, isoboroniae(meth)acrylate, phenyl(meth)acrylate, and phenoxyethyl(meth)acrylate; hydroxyalkyl (meth)acrylates, such as hydroxyethyl(meth)acrylate, hydroxypropyl(meth)acrylate, and pentaerythritol tri(meth)acrylate; alkoxyalkylene glycol mono(meth)acrylates, such as methoxyethyl(meth)acrylate and ethoxyethyl (meth)acrylate; alkylene polyol poly(meth)acrylates, such as ethylene glycol di(meth)acrylate, butanediol di(meth)acrylate, neopentyl glycol di(meth)acrylate, 1,6-hexanediol di(meth)acrylate, trimethylolpropane tri(meth)acrylate, pentaerythritol tetra(meth)acrylate, and dipentaerythritol hexa(meth)acrylate; polyoxyalkylene glycol poly(meth)acrylates, such as diethylene glycol di(meth)acrylate, triethylene glycol di(meth)acrylate, ethoxylated trimethylolpropane triacrylate, and propoxylated trimethylolpropane tri(meth)acrylate; poly(meth)acrylates, such as hydroxypivalic acid neopentyl glycol ester di(meth)acrylate; and isocyanurate-type poly(meth)acrylates, such as tris[(meth)acryloxyethyl]isocyanurate, and these may be used alone or in combination of two or more.

In the photosensitive resin composition of the present disclosure, the (meth)acrylic resin may be an unsaturated polyester-based oligomer, a (meth)acrylate-based oligomer, or the like, and may be, for example, a hexafunctional flexible acrylic oligomer. The mixing amount of the (meth)acrylic resin may be 1 to 15 wt %, 1 to 10 wt %, or 5 to 10 wt %, relative to the total composition. The composition includes a solid and a solvent. When the content of the (meth)acrylic resin is within the above range, excellent resolution and undercut can be obtained and a coating film can be cured to an appropriate level.

### <Heat Curing Catalyst>

In the composition of the present disclosure, at least any one type of a curing agent or a curing catalyst may be further added as a heat curing catalyst. For example, the heat curing catalyst may not overlap the components (A) to (G) described above.

Examples of the curing agent may include polyfunctional phenol compounds, polycarboxylic acids and acid anhydrides thereof, aliphatic or aromatic primary or secondary amines, polyamide resins, isocyanate compounds, polymercapto compounds, and the like. The curing agent may be, for example, a polyfunctional phenolic compound, polycarboxylic acid, and an acid anhydride thereof. The use of these curing agents can ensure excellent workability and insulation. The polyfunctional phenol compound may be particularly limited as long as the compound has two or more phenolic hydroxyl groups in one molecule, and may be, for example, a well-known and commonly used compound. Examples of the polyfunctional phenol compound may include a phenol novolac resin, a cresol novolac resin, bisphenol A, allylated bisphenol A, bisphenol F, a novolac resin of bisphenol A, and a vinylphenol copolymer resin. The polyfunctional phenol compound may be, for example, bisphenol A, and consequently, high reactivity and high heat resistance can be ensured. The polyfunctional phenol compound can undergo an addition reaction with at least one type of an epoxy compound or an octane compound in the presence of an appropriate curing catalyst. The polycarboxylic acids and acid anhydrides thereof may be compounds having two or more carboxyl groups in one molecule and acid anhydrides thereof, and may include, for example, (meth)acrylic acid copolymers, maleic anhydride copolymers, dibasic acid condensation products, and the like. Examples of commercially available products may include Joncryl (product group name) by BASF Company, SMA Resins (product group names) by Sartomer Company, and a polyazelaic polyanhydride by New Japan Chemical Co., Ltd.

The curing catalyst is a compound capable of becoming a curing catalyst in reactions between a curing agent and heat-curable resins, such as an epoxy compound and an oxetane compound, or a polymerization catalyst when a curing agent is not used. Specific examples of the curing catalyst may include tertiary amines, tertiary amine salts, quaternary ammonium salts, tertiary phosphines, crown ether compounds, and phosphonium ylides, which may be used alone or in combination of two or more thereof.

Examples of the curing catalyst may include: imidazoles, such as trade names 2E4MZ, C11Z, C17Z, and 2PZ; imidazole AZINE compounds, such as trade names 2MZ-A and 2E4MZ-A; isocyanurates of imidazoles, such as trade names 2MZ-OK and 2PZ-OK; imidazolyhydroxymethyl compounds, such as trade names 2PHZ and 2P4MHZ (Shikoku Kasei Industrial Co., Ltd.); dicyandiamide and derivatives thereof; melamine and derivatives thereof; diaminomalonitrile and derivatives thereof; amines, such as diethylenetriamine, triethylenetetramine, tetraethylenepentamine, bis(hexamethylene)triamine, triethanolamine, and diaminodiphenylmethane; 1,8-diazabicyciro[5,4,0]undecene-7 (trade name DBU, San-Apro Co., Ltd.); 3,9-bis(3-aminopropyl)-2,4,8,10-tetraoxaspiro[5,5]undecane (trade name ATU, Ajinomoto Co., Ltd.); or organophosphine compounds, such as triphenylphosphine, tricyclohexylphosphine, tributylphosphine, and methyldiphenylphosphine.

In the photosensitive resin composition of the present disclosure, the curing catalyst may be an amine-based, phosphine-based, or imidazole-based curing catalyst, and may be for example a melamine-based amine curing catalyst. The mixing amount of the curing catalyst may be 0.1 to 10 wt %, 0.1 to 5 wt %, or 0.1 to 3 wt %, relative to the total composition.

When the content of the curing catalyst is within the above range, a coating film can be sufficiently cured to exhibit excellent adhesion, pencil hardness, and heat resistance, ensure an appropriate time of curing, and prevent the deterioration in developability.

### <Anti-Oxidant>

The photosensitive resin composition of the present disclosure may also include an antioxidant. The including of the antioxidant can prevent the oxidation degradation of curable resins or the like, thereby suppressing discoloration, while obtaining the enhancement in heat resistance and favorable resolution (reproducibility of line width). In other words, a white colorant may degrade the resolution by reflecting and absorbing light depending on its type, but the including of the anti-oxidant can achieve good resolution regardless of the type of white colorant. The anti-oxidants may be a radical scavenger that neutralizes generated radicals, or a peroxide decomposition inhibitor that decomposes generated peroxides into harmless substances and prevents the generation of new radicals, and may be used alone or in a combination of two or more thereof.

Examples of the anti-oxidant having an effect as a radical scavenger may include: phenolic compounds, such as hydroquinone, 4-t-butylcatechol, 2-t-butylhydroquinone, hydroquinone monomethyl ether, 2,6-di-t-butyl-p-cresol, 2,2-methylene-bis(4-methyl-6-t-butylphenol), 1,1,3-tris(2-methyl-4-hydroxy-5-t-butylphenyl)butane, 1,3,5-trimethyl-2,4,6-tris(3,5-di-t-butyl-4-hydroxybenzyl)benzene, and 1,3,5-tris(3′,5′-di-t-butyl-4-hydroxybenzyl)-S-triazine-2,4,6-(1H, 3H, 5H)trione; quinone-based compounds, such as methaquinone and benzoquinone; amine-based compounds, such as bis(2,2,6,6-tetramethyl-4-piperidyl)-sebacate and phenothiazine. For example, IRGANOX1010 (trade name, BASF Japan Co., Ltd.) and the like may be used as a commercially available product.

Examples of the anti-oxidant having an effect as peroxide decomposer may include: phosphorus compounds, such as triphenylphosphite; and sulfur compounds, such as pentaerythritol tetra lauryl thiopropionate, dilauryl thiopropionate, and distearyl-3,3′-thiodipropionate.

For example, the anti-oxidant may be a phenolic compound, and the use of such a compound can suppress discoloration, enhance heat resistance, and reproduce a more favorable resolution.

The anti-oxidant, such as a phenolic anti-oxidant, may be used in combination with a heat resistance stabilizer. Such a combination can exhibit a greater effect.

Examples of the heat resistance stabilizer may include phosphorus-based, hydroxylamine-based, and sulfur-based heat-resistant stabilizers. Such heat resistance stabilizers may be used alone or in a combination of two or more thereof.

For example, the anti-oxidant may be a hydroxylamine-based anti-oxidant, a sulfur-based anti-oxidant, or a phenolic anti-oxidant. In the use of the phenolic anti-oxidant, the mixing amount of the phenolic anti-oxidant may be 0.01 to 5 wt % or 0.03 to 3 wt %, relative to the total composition. When the mixing amount of the anti-oxidant exceeds 0.01 to 1 wt %, an effect resulting from the addition of the anti-oxidant can be certainly obtained. When the mixing amount is 1 wt % or less, a favorable alkaline phenomenon can be obtained without the interruption of a photoreaction, and favorable dryness to touch or coating film properties can be ensured.

### <Organic Solvent>

The photosensitive resin composition of the present disclosure may include an organic solvent for the purpose of preparing a composition or adjusting viscosity when applied to a substrate or a base film. Examples of the organic solvent may include: esters; aliphatic hydrocarbons, such as octane and decane; petroleum-based solvents, such as petroleum ether, petroleum naphtha, and solvent naphtha; and well-known and commonly used organic solvents. These organic solvents may be used alone or in a combination of two or more thereof.

### <Other Additives>

Additionally, the photosensitive resin composition of the present disclosure may include other additives that are well known and commonly used in the field of electronic materials. Examples of other additives may include a heat polymerization inhibitor, an ultraviolet absorber, a plasticizer, a flame retardant, an anti-static agent, an anti-aging agent, an antimicrobial and anti-mold agent, an anti-foaming agent, a leveling agent, a thickener, an adhesion provider, a thixotropic agent, a photo-initiation aid, a sensitizer, a curing accelerator, a release agent, a surface treatment agent, a dispersant, a dispersion aid, a surface modifier, a stabilizer, and the like.

In the photosensitive resin composition of the present disclosure, the content of phosphorus may be 500 to 5000 ppm.

In the photosensitive resin composition, a content of phosphorous of 500 ppm or more can improve surface curing and enhancing gold plating resistance and adhesion, and a content of phosphorus of 5000 ppm or less can show an effect of increasing reaction rates of the silicone encapsulant.

A content of phosphorous of less than 500 ppm may result in a pencil hardness of 3H, poor adhesion after gold plating, low glass, and incomplete formation of solder resist openings (SRO). However, a content of phosphorous of more than 5,000 ppm may result in very low reaction rates of the silicone encapsulant, low developability and reflectance, and incomplete formation of SRO.

### [Dry Film and Manufacturing Method Thereof]

Another aspect of the present disclosure relates to a dry film having a photosensitive resin layer formed by applying and drying the photosensitive resin composition on a first film.

To manufacture the dry film, the composition of the present disclosure is first diluted with an organic solvent to have an appropriately adjusted viscosity, and then applied on the first film to a uniform thickness, for example, 40 to 60 μm, by a comma coater, a blade coater, a lip coater, a rod coater, a squeeze coater, a reverse coater, a transfer roll coater, a gravure coater, a micro gravure coater, a spray coater, or the like. Subsequently, the applied composition may be typically dried at a temperature of 40 to 120 °C for 1 to 30 minutes to form a photosensitive resin layer, ultimately manufacturing a dry film.

The thickness of the applied film is not particularly limited, but generally, the thickness after drying may be 10 to 150 μm, 10 to 80 μm, or 10 to 60 km.

As the first film, a plastic film may be used, and for example, a polyester film such as polyethylene terephthalate (PET), a polyimide film, a polyamideimide film, a polypropylene film, a polystyrene film, or the like may be used. For example, the plastic film may be polyethylene terephthalate. The thickness of the first film is not particularly limited, but generally, the thickness is appropriately selected within the range of 10 to 150 μm. The composition may be applied to a metal foil, such as a copper foil or an aluminum foil. The first film that has been used may undergo peeling treatment with acryl, silicone, or the like.

The dry film of the present disclosure is white, and thus may be used to reflect light generated from a light emitting diode (LED) or electroluminescence (EL) used as a light source in a lighting fixture or a backlight for a liquid crystal display, such as a mobile terminal, a laptop computer, a tablet PC, a monitor, a smartphone, a personal computer, or a television. The dry film of the present disclosure may be applied to an LED, a light emitting PCB, and the like.

In order to prepare a cured film on a printed circuit board by using the dry film, a second film for the purpose of protecting the dry film is peeled off, and an exposed resin layer of the dry film is overlaid and attached onto a substrate with circuits by using a laminator or the like, thereby forming the resin layer on the substrate with circuits. Subsequently, the formed resin layer may be subjected to exposure, development, heating, and then curing, thereby forming a cured film. The second film may be peeled off at any step, either before or after exposure.

### [Cured Product and Preparation Method Thereof]

The cured product of the present disclosure may be obtained by curing the photosensitive resin composition of the present disclosure or a solder resist layer of the dry film of the present disclosure.

The cured product of the present disclosure may be suitably used for printed circuit boards, electronic parts, and the like. The cured product of the present disclosure has high cracking resistance, high resolution, and outstanding dielectric properties including low dielectric constant and low dielectric tangent. In addition, the cured product of the present disclosure may be excellent in terms of heat resistance and a coefficient of linear expansion.

For example, the cured product of the present disclosure may be a solder resist.

The solder resist may be prepared by applying the photosensitive resin composition of the present disclosure on a substrate to form a photosensitive resin layer, selectively exposing the photosensitive resin layer through a photo-mask with a predetermined pattern by active energy rays, and then developing an unexposed portion with an aqueous alkaline solution (e.g., 0.3 to 3 wt % of an aqueous sodium carbonate solution) to form a pattern. Alternatively, in cases of the dry film, the first film of the dry film is peeled off and then developed, after exposure, thereby forming a solder resist patterned on a substrate. The first film may be peeled off from the dry film before exposure, followed by exposure and development of an exposed resin layer, as long as it is in a range not to impair characteristics.

[Printed Circuit board and Manufacturing Method Thereof]

The printed circuit board of the present disclosure may include a cured product of the photosensitive resin composition of the present disclosure or a cured film obtained by curing the photosensitive resin layer of the dry film of the present disclosure.

The printed circuit board of the present disclosure may include a cured product obtained from the photosensitive resin composition of the present disclosure or the photosensitive resin layer of the dry film. In a manufacturing method of the printed circuit board of the present disclosure, for example, the viscosity of the photosensitive resin composition of the present disclosure is adjusted to be suitable for an application method by using the organic solvent, and this photosensitive resin composition is applied onto a substrate by a method, such as dip coating, flow coating, roll coating, bar coating, screen printing, or curtain coating, and then organic solvents included in the composition are volatilized and dried (pre-dried) at a temperature of 60 to 100 °C to form a tacky free resin layer. In cases of the dry film, the resin layer is bonded to the substrate to make contact with the substrate by a laminator or the like, and then the first film is detached to form the resin layer on the substrate.

Examples of the substrate may include not only printed circuit boards and flexible printed circuit boards with circuits formed of copper and the like, but also FR-4 substrates and copper clad laminates of all grades (FR-4, etc.), which use materials of copper clad laminate sheets for high-frequency circuits, utilizing paper phenol, paper epoxy, glass fiber epoxy, glass polyimide, glass fiber/epoxy, glass fiber/paper epoxy, synthetic fiber epoxy, fluoroplastic-polyethylene-polyphenylene ether, polyphenylene oxide cyanate, or the like, and other metal substrates, polyimide films, polyethylene terephthalate films, polyethylene naphthalate (PEN) films, glass substrates, ceramic substrates, wafer substrates, and others.

The laminating of the dry film on the substrate may be carried out after pressurization and heating using a vacuum laminator or the like. The utilization of such a vacuum laminator, when employing a substrate with circuits, enables the dry film to adhere to the circuit substrate in spite of irregularities on the surface of the circuit substrate, thereby preventing the incorporation of air bubbles and improving the relief of dents on the substrate surface. The pressurization condition may be about 0.1 to 2.0 MPa, and the temperature condition may be 40 to 120 °C.

Additionally, the cured product is subjected to post-curing through i) active energy ray irradiation followed by heat curing (e.g., 100 to 220 °C), ii) heat curing followed by active energy ray irradiation, iii) only active energy ray irradiation, or iv) only heat curing, thereby forming a cured film with excellent properties, such as adhesion and hardness.

The cured product of the present disclosure is cured by heating at a temperature of for example 100 to 220 °C, thereby forming a cured film with excellent overall properties, such as high reflectance, outstanding yellowing resistance, and superb crack resistance.

An exposure apparatus used for the active energy ray irradiation may be an apparatus that is equipped with a high-pressure mercury lamp, an ultra-high-pressure mercury lamp, a metal halide lamp, a mercury shot arc lamp, or the like and irradiates ultraviolet (UV) rays in the range of 350 to 450 nm, or a direct drawing device (e.g., a laser direct imaging device where a computer directly draws CAD data by a laser) may be used. A direct drawing lamp light source or a laser light source may have a maximum wavelength in the range of 350 to 450 nm. The exposure for image formation varies depending on the thickness or the like, but may be generally 10 to 1000 mJ/cm² or 20 to 800 mJ/cm².

The development may be performed by a dipping method, a shower method, a spray method, a brush method, or the like, and an aqueous alkaline solution, such as potassium hydroxide, sodium hydroxide, sodium carbonate, potassium carbonate, sodium phosphate, sodium silicate, ammonia, or an amine may be used as a developing solution.

The printed circuit board of the present disclosure may include a dry film including one or more layers formed from the photosensitive resin composition.

In the formation of the printed circuit board, the dry film may be placed on a test substrate and may be transferred onto the test substrate by vacuum lamination.

Thereafter, the first film is peeled off, and the substrate onto which the dry film with the first film peeled off has been transferred may be subjected to UV exposure by using an exposure apparatus. In the case of such exposure, the exposed portion (light-irradiated portion) may be cured. After the exposure, the substrate is cooled at room temperature, and then placed in a development device to develop the unexposed portion with an aqueous alkali solution, completing the formation of a resist pattern. The substrate on which the pattern has been formed through development is post-cured in an oven at 150 °C for 1 hour, completing substrate manufacturing. After the post-curing, a reflow process is performed and then a chip mounting process is performed. Afterwards, an encapsulation process is performed by preparing a silicone encapsulant on the cured product of the photosensitive resin layer. The photosensitive resin composition of the present disclosure can reduce the outgassing of the photopolymerization initiator, thereby solving yellowing and incomplete curing of the silicone encapsulant formed on the cured product and improving the reaction rate of the silicone encapsulant.

In the method of manufacturing a printed circuit board including a cured product of the present disclosure, for example, the first film may be peeled off after an exposure process followed by a lamination process.

### [Silicone Encapsulant Layer and Preparation Method Thereof]

The printed circuit board of the present disclosure may further include a silicone encapsulant layer disposed on the cured product (obtained by curing the photosensitive resin layer). The silicone encapsulant layer may be formed by coating a composition including silicone in order to encapsulate and protect the printed circuit board or solder resist layer.

In order to protect a chip portion that emits light and the photosensitive resin layer (or the cured product obtained by curing the photosensitive resin layer), the above-described silicone encapsulant layer may be coated.

Hereinafter, an exemplary preparation method of the silicone encapsulant layer will be described.

Dams with a width of 2.0 cm, a height of 2.0 cm, and a thickness of 250-300 μm are manufactured on the printed circuit board that has post-cured or reflowed, and then a 1:1 mixture of any silicone encapsulants A and B is added thereto to apply a silicone encapsulant with a thickness of 250 to 300 μm. Thereafter, the silicone encapsulant undergoes primary curing by curing at 100 °C for 2 hours in an oven and secondary curing by curing at 150 °C for 4 hours in an oven, thereby preparing a silicone encapsulant layer.

To measure physical properties of the silicone encapsulant layer, the reaction rate of the silicone encapsulant and the content of the photopolymerization initiator remaining in the silicone encapsulant layer may be analyzed after peeling off the silicone encapsulant layer following the completion of curing. In addition, the extent of curing may be checked by measuring the degree of curing (reaction rate) of the silicone encapsulant. The reflectance of the silicone encapsulant layer may also be measured.

For example, the silicone encapsulant layer may include a lower encapsulant region that is close to the solder resist layer and an upper encapsulant region that is far from the solder resist layer.

For example, the content of the photopolymerization initiator (E) included in the upper encapsulant region or the lower encapsulant region may be 1,000 ppm or less, 900 ppm or less, 800 ppm or less, 700 ppm or less, 600 ppm or less, or 500 ppm or less, relative to the content of the photopolymerization initiator (E) included in the solder resist layer.

The content of the photopolymerization initiator included in the upper encapsulant region or the lower encapsulant region is derived from the transfer of the photopolymerization initiator included in the solder resist layer. That is, (E) the photopolymerization initiator of a trimethylbenzoyl phosphine oxide-based compound having at least one P—O bond of the present disclosure can be used to decrease the content of the photopolymerization initiator transferred to the nearby upper or lower encapsulant regions.

For example, when the photopolymerization initiator is transferred to the silicone encapsulant layer due to outgas diffusion of the photopolymerization initiator, the silicone encapsulant is incompletely cured by an inhibition reaction between a phosphorus (P) component of the photopolymerization initiator and a catalyst component (e.g., platinum catalyst) of the silicone encapsulant layer, resulting in a reduction in the reaction rate of the silicone encapsulant. The reduction in the reaction rate of the silicone encapsulant may cause a problem associated with long-term reliability.

### [Protective Film]

The laminate of the present disclosure may include the cured product and a protective film.

In the present disclosure, the protective film may be attached after the photosensitive resin layer is post-cured to form the cured product, in order to remove the photopolymerization initiator. The attachment of the protective film enables efficient removal of the photopolymerization initiator remaining in the solder resist layer due to high affinity of the protective film for the photopolymerization initiator. The removal of the remaining photopolymerization initiator can decrease the content of the photopolymerization initiator remaining after the flowing and firing processes. This decreased content of the photopolymerization initiator leads to an increased reaction rate of the silicone encapsulant when the silicone encapsulant is coated on the cured product layer, and the increased reaction rate can significantly improve long-term reliability.

The protective film may employ, for example, a polyethylene film, a polytetrafluoroethylene film, a polypropylene film, a surface-treated paper, or the like. The thickness of the protective film is not particularly limited, but may be, for example, 10 to 150 μm.

For example, the content of the photopolymerization initiator (E) included in the protective film may be 1000 ppm or less relative to the content of the photopolymerization initiator (E) included in the solder resist layer.

The content of the photopolymerization initiator included in the protective film is derived from the transfer of the photopolymerization initiator included in the solder resist layer. That is, (E) the photopolymerization initiator of a trimethylbenzoyl phosphine oxide-based compound having at least one P—O bond of the present disclosure can be used to decrease the content of the photopolymerization initiator transferred to the nearby protective film.

### EXAMPLE

Hereinafter, the present disclosure will be described in detail with reference to examples. The present disclosure is limited to the following examples.

### Synthesis Example 1: Alkali-Soluble Resin A, Copolymer Resin

In a flask equipped with a thermometer, a stirrer, a dropping funnel, and a reflux condenser, 325.0 parts by weight of dipropylene glycol monomethyl ether as a solvent was heated to 110 °C, and a mixture of 174.0 parts by weight of methacrylic acid, 174.0 parts by weight of F-caprolactone modified methacrylic acid (average molecular weight: 314), 77.0 parts by weight of methyl methacrylate, 222.0 parts by weight of dipropylene glycol monomethyl ether, and 12.0 parts by weight of t-butylperoxy-2-ethylhexanoate (Perbutyl-O by Nichiyu) as a polymerization catalyst was added dropwise over 3 hours, and stirred at 110 °C for 3 hours, followed by deactivation of the polymerization catalyst, thereby obtaining a resin solution. This resin solution was cooled, and then 289.0 parts by weight of Cyclomer M100 (Daicel), 3.0 parts by weight of triphenylphosphine, and 1.3 parts by weight of hydroquinone monomethyl ether were added. The temperature was raised to 100 °C, and the mixture was stirred to perform a ring-opening addition reaction of an epoxy ring, thereby obtaining Resin Solution A. The solid content of the obtained Resin Solution A was 54.5 wt %, and the acid value of the solid content was 79.8 mgKOH/g.

### Synthesis Example 2: Resin Solution D

In an internal pressure vessel equipped with a thermometer, a cooling tube, and a stirrer, 200 parts by weight of deionized water and 0.3 parts by weight of sodium sulfate were injected and confirmed to have dissolved. Thereafter, 5 parts by weight of benzoyl peroxide (BPO) as a polymerization initiator and 5 parts by weight of α-methylstyrendimer (MSD) as a chain transfer agent were added to a monomer mixture including 10.4 parts by weight of methylmethacrylate (MMA), 5 parts by weight of n-butylacrylate (n-BA), 24.6 parts by weight of methacrylic acid (MAA), and 60 parts by weight of styrene, and sufficiently dissolved. Thereafter, a dispersant was added to a concentration of 300 ppm, and the inside of the kiln was replaced with nitrogen by sufficient stirring, and then the temperature was raised to perform suspension polymerization. After the polymerization was completed, the obtained suspension was filtered through a 30-μm mesh, and dried with hot air at 40 °C, thereby obtaining a resin in a grain state. The obtained grain resin (copolymer resin) was sufficiently dissolved using dipropylene glycol methyl ether (DPM) as an organic solvent to achieve a solid concentration of 50 wt %, and this solution was referred to as Resin Solution D. The solid acid value was 160 mgKOH/g.

### Synthesis Example 3: Carboxyl Group-Containing Cresol Novolac Epoxy Acrylate Resin A-2

In a four-neck flask equipped with a stirrer and a reflux condenser, 220 parts by mass of a cresol novolac type epoxy resin was placed, and 214 parts by mass of carbitol acetate were added, followed by dissolution by heating. Then, 0.1 parts by mass of hydroquinone as a polymerization inhibitor and 2.0 parts by mass of dimethylbenzylamine as a reaction catalyst were added, thereby preparing a mixture. This mixture was heated to 95 to 105 °C, and 72 parts by mass of acrylic acid was slowly added dropwise, followed by reaction for 16 hours. This reaction product was cooled to 80 to 90 °C, and then 106 parts by mass of a tetrahydrophthalic anhydride was added to conduct reaction for 8 hours, followed by cooling, and then the content was taken out.

The photosensitive resin having an ethylenically unsaturated bond and a carboxyl group thus obtained had a non-volatile content of 64%, a solid acid value of 84.4 mg KOH/g, and a weight average molecular weight (Mw) of about 7,500. Hereinafter, this resin is referred to as (A-2). The weight average molecular weight of the obtained resin was measured by GPC.

### Preparation of Photosensitive Resin Composition

TABLE 1
Contents of respective components of photosensitive resin composition (unit: basedon mass % relative to the total composition,
each value being rounded to the third decimal place, provided that in Example 2, the weight % was calculated relative to the
total weight of the composition of Example 1)

| | Example | Example | Example | Example | Example | Example | Example | Example | Example | Example |
|---|---|---|---|---|---|---|---|---|---|---|
| Ingredient | 1 | 2 | 3 | 4 | 5 | 6 | 7 | 8 | 9 | 10 |
| (A) | 12.50 | 12.50 | 12.50 | 12.50 | 12.50 | 12.50 | 32.00 | 32.00 | 32.00 | 32.00 |
| (A-1) | 0.00 | 0.00 | 0.00 | 0.00 | 0.00 | 0.00 | 0.00 | 0.00 | 0.00 | 0.00 |
| (A-2) | 0.00 | 0.00 | 0.00 | 0.00 | 0.00 | 0.00 | 0.00 | 0.00 | 0.00 | 0.00 |
| (A-3) | 0.00 | 0.00 | 0.00 | 0.00 | 0.00 | 0.00 | 0.00 | 0.00 | 0.00 | 0.00 |
| (B) Titanium | 47.70 | 47.04 | 47.70 | 47.70 | 24.35 | 0.00 | 60.00 | 62.00 | 54.00 | 65.00 |
| oxide | | | | | | | | | | |
| (B) Silica | 1.00 | 1.00 | 1.00 | 1.00 | 24.35 | 24.35 | 1.00 | 1.00 | 1.00 | 1.00 |
| (B)BaSO₄ | 0.00 | 0.00 | 0.00 | 0.00 | 0.00 | 24.35 | 0.00 | 0.00 | 0.00 | 0.00 |
| (C) | 1.50 | 1.50 | 1.50 | 1.50 | 1.50 | 1.50 | 0.00 | 3.00 | 0.00 | 0.00 |
| (D) | 2.50 | 2.50 | 2.50 | 2.50 | 2.50 | 2.50 | 5.00 | 0.00 | 0.00 | 0.00 |
| (F) | 0.50 | 0.50 | 0.50 | 0.50 | 0.50 | 0.50 | 0.00 | 0.00 | 0.00 | 0.00 |
| (G) | 11.00 | 11.00 | 11.00 | 11.00 | 11.00 | 11.00 | 0.00 | 0.00 | 11.0 | 0.00 |
| Photopoly- | 0.00 | 0.00 | 0.00 | 0.00 | 0.00 | 0.00 | 0.00 | 0.00 | 0.00 | 0.00 |
| merization | | | | | | | | | | |
| initiator A | | | | | | | | | | |
| Photopoly- | 2.00 | 2.66 | 0.00 | 1.00 | 0.00 | 0.00 | 0.00 | 0.00 | 0.00 | 0.00 |
| merization | | | | | | | | | | |
| initiator E-1 | | | | | | | | | | |
| Photopoly- | 0.00 | 0.00 | 2.00 | 1.00 | 2.00 | 2.00 | 2.00 | 2.00 | 2.00 | 2.00 |
| merization | | | | | | | | | | |
| initiator E-2 | | | | | | | | | | |
| Photopoly- | 0.60 | 0.60 | 0.60 | 0.60 | 0.60 | 0.60 | 0.00 | 0.00 | 0.00 | 0.00 |
| merization | | | | | | | | | | |
| initiator | | | | | | | | | | |
| (Oxime- | | | | | | | | | | |
| based) | | | | | | | | | | |
| Epoxy resin | 9.50 | 9.50 | 9.50 | 9.50 | 9.50 | 9.50 | 0.00 | 0.00 | 0.00 | 0.00 |
| (Meta)acrylic | 9.50 | 9.50 | 9.50 | 9.50 | 9.50 | 9.50 | 0.00 | 0.00 | 0.00 | 0.00 |
| resin | | | | | | | | | | |
| Heat curing | 1.00 | 1.00 | 1.00 | 1.00 | 1.00 | 1.00 | 0.00 | 0.00 | 0.00 | 0.00 |
| catalyst | | | | | | | | | | |
| Dispersant | 0.50 | 0.50 | 0.50 | 0.50 | 0.50 | 0.50 | 0.00 | 0.00 | 0.00 | 0.00 |
| Anti-oxidant | 0.20 | 0.20 | 0.20 | 0.20 | 0.20 | 0.20 | 0.00 | 0.00 | 0.00 | 0.00 |
| Total | 100.00 | 100.00 | 100.00 | 100.00 | 100.00 | 100.00 | 100.00 | 100.00 | 100.00 | 100.00 |

| | Comparative | Comparative | Comparative | Comparative | Comparative | Comparative | Comparative |
|---|---|---|---|---|---|---|---|
| Ingredient | Example 1 | Example 2 | Example 3 | Example 4 | Example 5 | Example 6 | Example 7 |
| (A) | 12.50 | 0.00 | 0.00 | 0.00 | 12.50 | 12.50 | 32.00 |
| (A-1) | 0.00 | 12.50 | 0.00 | 0.00 | 0.00 | 0.00 | 0.00 |
| (A-2) | 0.00 | 0.00 | 12.50 | 0.00 | 0.00 | 0.00 | 0.00 |
| (A-3) | 0.00 | 0.00 | 0.00 | 12.50 | 0.00 | 0.00 | 0.00 |
| (B) Titanium | 47.70 | 47.70 | 47.70 | 47.70 | 49.70 | 43.70 | 65.00 |
| oxide | | | | | | | |
| (B) Silica | 1.00 | 1.00 | 1.00 | 1.00 | 1.00 | 1.00 | 1.00 |
| (B)BaSO₄ | 0.00 | 0.00 | 0.00 | 0.00 | 0.00 | 0.00 | 0.00 |
| (C) | 1.50 | 1.50 | 1.50 | 1.50 | 1.50 | 1.50 | 0.00 |
| (D) | 2.50 | 2.50 | 2.50 | 2.50 | 2.50 | 2.50 | 0.00 |
| (F) | 0.50 | 0.50 | 0.50 | 0.50 | 0.50 | 0.50 | 0.00 |
| (G) | 11.00 | 11.00 | 11.00 | 11.00 | 11.00 | 11.00 | 0.00 |
| Photopoly- | 2.00 | 2.00 | 2.00 | 2.00 | 0.00 | 6.00 | 2.00 |
| merization | | | | | | | |
| initiator A | | | | | | | |
| Photopoly- | 0.00 | 0.00 | 0.00 | 0.00 | 0.00 | 0.00 | 0.00 |
| merization | | | | | | | |
| initiator E-1 | | | | | | | |
| Photopoly- | 0.00 | 0.00 | 0.00 | 0.00 | 0.00 | 0.00 | 0.00 |
| merization | | | | | | | |
| initiator E-2 | | | | | | | |
| Photopoly- | 0.60 | 0.60 | 0.60 | 0.60 | 0.60 | 0.60 | 0.00 |
| merization | | | | | | | |
| initiator | | | | | | | |
| (Oxime- | | | | | | | |
| based) | | | | | | | |
| Epoxy resin | 9.50 | 9.50 | 9.50 | 9.50 | 9.50 | 9.50 | 0.00 |
| (Meta)acrylic | 9.50 | 9.50 | 9.50 | 9.50 | 9.50 | 9.50 | 0.00 |
| resin | | | | | | | |
| Heat curing | 1.00 | 1.00 | 1.00 | 1.00 | 1.00 | 1.00 | 0.00 |
| catalyst | | | | | | | |
| Dispersant | 0.50 | 0.50 | 0.50 | 0.50 | 0.50 | 0.50 | 0.00 |
| Anti-oxidant | 0.20 | 0.20 | 0.20 | 0.20 | 0.20 | 0.20 | 0.00 |
| Total | 100.00 | 100.00 | 100.00 | 100.00 | 100.00 | 100.00 | 100.00 |

Resin Solution A synthesized above (weight average molecular weight: g/mol)
(A-1) EPICLON R-2000K, manufactured by DIC Co., Ltd., Japan: containing cresol novolac (weight average molecular weight: 7,500 g/mol)
(A-2) EPICLON R-2000, manufactured by DIC Co., Ltd., Japan: containing cresol novolac (weight average molecular weight: 7,500 g/mol, acid value: 54 mgKOH/g, solid acid value: 84.4 mgKOH/g, and solid content: 64 wt %)
(A-3) ZAR-1035, manufactured by Nippon Chemical Co., Ltd .: containing bisphenol (weight average molecular weight: 8,000 g/mol, solid acid value: 100 mgKOH/g, solid content: 64 wt %)
(B) Rutile-type titanium oxide, R-931 manufactured by DuPont Co., Ltd .: (average particle size: 0.36 μm)
(B) Silica ADMAFINE SO-E2 manufactured by Admatex
(B) Barium sulfate (BaSO₄, B-30, manufactured by Sakai Chemical Co., Ltd.)
(C) Mercapto-modified (meth)acrylate, ES11ON Miwon Specialty Chemical Co., Ltd. (weight average molecular weight: 340 g/mol, obtained by mixing pentaerythritol tetrakis(3-mercaptopropionate) and trimethylolpropane triacrylate obtained)
(D) Resin Solution D synthesized above
(F) Silane coupling agent, KBE-403, manufactured by Shinetsu Chemical Co., Ltd. (3-glycidoxy propyltriethoxysilane)
(G) Ebecryl 210 resin with urethane bond, manufactured by Daicel-Allnex Co., Ltd. (aromatic urethane diacrylate oligomer)
Photopolymerization Initiator A: 2,4,6-Trimethylbenzoyldiphenylphosphine oxide
Photopolymerization Initiator E-1: Omnipol TP (manufactured by IGM Resins) (a + b + c = 1 to 20) 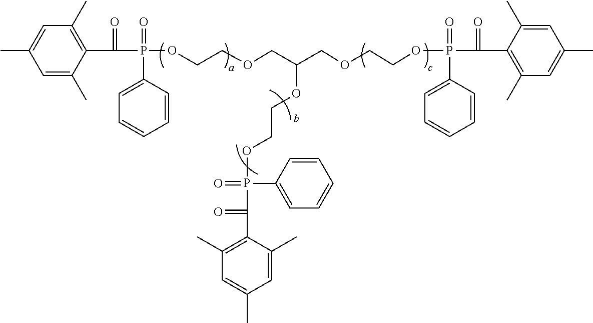
Photopolymerization Initiator E-2: Omnirad TPO L (manufactured by IGM Resins) 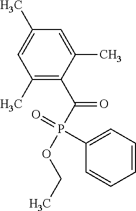 [SMILES: CCOP(=O)(C(=O)c1c(C)cc(C)cc1C)c1ccccc1]
Photopolymerization initiator, oxime-based: Oxime ester initiator IRGACURE OXE02 (manufactured by BASF Japan Co. Ltd.)
Epoxy resin: jER828 (bisphenol A type epoxy resin, manufactured by Mitsubishi Chemical)
Acrylic resin: KAYARAD DPCA-60, manufactured by Japan Explosives Co., Ltd.
Heat curing catalyst: melamine, dicyandiamide, manufactured by Mitsubishi Chemical
Dispersant: Disperbyk-110, manufactured by BYK Co., Ltd.
Anti-oxidant: phenolic anti-oxidant IRGANOX1010 (manufactured by BASF Japan Co., Ltd.)

### Preparation of Dry Film of Photosensitive Resin Composition

Each composition of the examples and comparative examples was applied to a uniform thickness (50 μm) on a first film (PET film; XD-500P manufactured by Toray Co., Ltd., film thickness: 25 μm) by using a comma coater in a dust-free room. (2) The applied resin composition was dried in four temperature chambers (Chamber 1: 60 °C, Chamber 2: 80 °C, Chamber 3: 100 °C, Chamber 4: 100 °C) in the range of 40 to 120 °C. (3) The properly dried coating film on the first film was bound to a second film (polypropylene, PP film) to prepare a dry film. Particularly, the thickness of the dried coating film was 60 μm.

### Evaluation Example 1: Measurement of Outgas Content, Silicone Encapsulant Reaction Rate, and Photopolymerization Initiator Contents

### 1. Measurement of Outgas Content

Each of the photosensitive resin compositions of the examples and comparative examples was laminated on a PET film by using a vacuum laminator (CVP-300, Nichigo-Morton) with a first chamber of a temperature 60 °C under the conditions of a vacuum pressure of 3 hPa and a vacuum time of 10 seconds, thereby preparing a dry film, and then the PET film was peeled off.

The whole-surface exposure was performed using a DI exposure apparatus manufactured by Screen, at 300 mJ/cm² measured by an integrated photometer, while setting 23 steps using the Kodak Step Tablet No. 2, (41 steps), as a photomask. Subsequently, development was performed with a 1.0% Na₂CO₃ aqueous solution at 30 °C for 60 seconds under the condition of a spray pressure of 0.2 MPa. Thereafter, curing was performed in an oven at 150 °C for 60 minutes to obtain a cured product of the photosensitive resin layer.

A powder sample was collected from the manufactured resist layer and placed in a thermal desorption unit (TDU) manufactured by GERSTEL CO., Ltd. Specifically, the powder sample was heated at 150 °C for 60 minutes, with a temperature rise rate of 60 °C/min starting from 30 °C, by using helium as a purge gas (50 ml/min), and then desorption and collection were performed at −50 °C. The collected outgas component was separated and analyzed in a gas chromatography mass spectrometer (8890/5977B) manufactured by Agilent Technologies Co., Ltd. to be quantified as conversion of n-dodecane, and then the weight % of the outgas component was measured based on the weight of the photopolymerization initiator included in the cured product of the photosensitive resin layer.

The measurement conditions in gas chromatography were as follows. Column: capillary column DB-1MS manufactured by Agilent Technologies (length of 30 m, inner diameter of 0.25 mm, and thickness 0.25 μm), Detector: MS (ITQ900), Carrier gas: helium, Injector temperature: 300 °C, Detector temperature: 230 °C, Column temperature conditions: initial temperature of 50 °C, holding at 50 °C for 2 minutes after specimen injection, temperature rising at 12 °C/sec to 300 °C, and holding for 10 minutes after reaching 300 °C. Separately, as described later, a silicone encapsulant was formed on the substrate (obtained by laminating a dry film of a photosensitive resin composition on an FR-4 Cu film and then peeling off PET), and then cured by heating at 100 °C for 2 hours following heating at 150 °C for 4 hours.

The outgas content, silicone reaction rate, and contents of photopolymerization initiator transferred to the silicone encapsulant and protective film in each of the examples and comparative examples were measured, and shown in Table 2 below. Respective measurement methods refer to the following description.

### [Measurement Method of Outgas Content]

The peak of the photopolymerization initiator was investigated by TD-GCMS analysis. The unit of the peak was expressed as μg/g, indicating the amount (μg) of gas generated in terms of n-dodecane per 1 g of sample, and the total outgas of the photopolymerization initiator peak was measured. Particularly, the ratio of the peak area of the photopolymerization initiator to the area of n-dodacane as the REF of GC-MS was calculated (calculation formula provided below).

area of analysis peak of photopolymerization initiator/area of measurement peak of n-dodecane Calculation Formula:

### 2. Measurement of Silicone Encapsulant Reaction Rate and Photopolymerization Initiator Content

### [Calculation of Silicone Encapsulant Reaction Rate and Photopolymerization Initiator Content]

(1) Each dry film of a photosensitive resin composition (white solder resist composition) was laminated on a FR-4 Cu film by using a vacuum laminator (CVP-300, Nichigo-Morton) with a first chamber of a temperature 60 °C under conditions of a vacuum pressure of 3 hPa and a vacuum time of 10 seconds, and then the PET film was peeled off.

Exposure was performed using a DI exposure apparatus manufactured by Screen Co., Ltd., at 300 mJ/cm² measured by an integrated photometer, while setting 23 steps using the Kodak Step Tablet No. 2, (41 steps), as a photomask. Then, development was performed with a 1.0% Na₂CO₃ aqueous solution at 30 °C for 60 seconds under the condition of a spray pressure of 0.2 MPa, and curing was performed in an oven at 150 °C for 60 minutes, thereby obtaining a cured product (solder resist layer) of the photosensitive resin layer.

Dams with a width of 2.0 cm, a height of 2.0 cm, and a thickness of 250-300 μm were manufactured and then attached to both ends of the cured product of the photosensitive resin layer on the FR-4 Cu film. A 1:1 mixture of silicone encapsulants A and B was added to a space formed by the dams to laminate silicone encapsulant layers with a thickness of 250 to 300 μm thereon. Thereafter, the silicone encapsulants were subjected to primary curing by curing at 100 °C for 2 hours in an oven and secondary curing by curing at 150 °C for 4 hours in an oven. After the completion of the secondary curing, the interface between the cured product of the photosensitive resin layer and the silicone encapsulant layer was separated using a knife. Then, an FT-IR system was used to measure the reaction rates of the upper encapsulant region and the lower encapsulant region of the silicone encapsulant layer and the curing degree of the silicone encapsulant in the silicone encapsulant layer on a ZnSe crystal plate.

### [Calculation Method of Silicone Reaction Rates]

1) A silicone sample not subjected to primary and secondary curing and a silicone sample subjected to up to secondary curing were prepared (the upper and the lower).
2) The uncured silicone and cured silicone were placed onto a ZnSe crystal plate, and FT-IR measurement was performed.
3) The reaction rate was calculated by comparing the Si—H peak of the cured silicone with that of a neighboring region (2160⁻¹), while the uncured silicone was used as REF (calculation formula provided below).

height of Si—H peak of cured silicone/height of Si—H peak of uncured silicone×100 Calculation Formula:

(2) The content of the photopolymerization initiator was measured using by gel permeation chromatography analysis while the silicone encapsulant separated by a knife was used.

Specifically, 0.05 g separated with a knife from the silicone encapsulant layer formed on the cured product of the photosensitive resin layer was prepared as an analyte sample for the secondary post-cured silicone encapsulant. The 0.05 g of analyte sample was dissolved in 10.0 g of THF and then filled into a vial. To dissolve the undissolved photosensitive resin composition in the solution, an ultrasonic vibrator was used for 5 minutes, thereby preparing a specimen. Thereafter, 100 μl of the sample was injected into gel permeation chromatography (GPC) equipment, and analysis was completed.

### [Calculation of Content of Photopolymerization Initiator Transferred to Protective Film]

A PF protective film was attached on the secondary cured silicone encapsulant and left at a temperature of 40 °C and a humidity of 90% for 24 hours. Thereafter, the PF protective film was peeled off, and then 0.05 g separated with a knife from the silicone encapsulant layer formed on the cured product of the photosensitive resin layer was prepared as an analyte sample for the PF protective film. The 0.05 g of the analyte sample was dissolved in 5.0 g of tetrahydrofuran (THF) and then filled into a vial. To dissolve the undissolved photosensitive resin composition in the solution, an ultrasonic vibrator was used for 5 minutes, thereby preparing a specimen. Thereafter, 100 μl of the sample was injected into gel permeation chromatography (GPC) equipment, and analysis was completed.

### [Gel Permeation Chromatography (GPC) Measurement Method and Measurement Conditions for Photopolymerization Initiator Content Analysis]

The sampled specimen was injected into the GPC equipment (GPC equipment name: E2695 separation module by water, Detector: 2998 PDA/2414 RI, Flow rate: 0.5 ml/min, Columns: HSP gel HR MB-L 2.0 and HSP gel HR 1.0, Measurement temperature: 4 °C, Mobile phase: THF). As for the calculation method, the peak at 382 nm, which is an absorption wavelength of TPO as a photopolymerization initiator, was quantified and analyzed. The sampled analyte specimen and TPO as a REF photopolymerization initiator sample were used. The same procedure was performed on specimens containing 1, 10, and 100 ppm TPO to obtain a calibration curve, and the calibration curve result obtained at each concentration was used to quantify the photopolymerization initiator included in the sample.

### (Evaluation of Outgas Content)

⊚: Outgas content<500 ppm
∘: 500 ppm≥outgas content<1,000 ppm
Δ: 1,000 ppm≥outgas content<2,000 ppm
X: 2,000 ppm≥outgas content

### (Evaluation of Reaction Rate of Upper Silicone Encapsulant)

⊚: 70%≥reaction rate of upper silicone encapasulant
∘: 55%≥reaction rate of upper silicone encapasulant<70%
Δ: 40%≥reaction rate of upper silicone encapasulant<55%
X: reaction rate of upper silicone encapasulant<40%

### (Evaluation of Reaction Rate of Lower Silicone Encapsulant)

⊚: 50%≥reaction rate of upper silicone encapasulant
∘: 40%≥reaction rate of lower silicone encapasulant<50%
Δ: 30%≥reaction rate of upper silicone encapasulant<40%
X: reaction rate of upper silicone encapasulant<30%

### (Content of Photopolymerization Initiator Transferred to Encapsulant)

⊚: photopolymerization initiator content<300 ppm
∘: 300 ppm≥photopolymerization initiator content<500 ppm
Δ: 500 ppm≥photopolymerization initiator content<700 ppm
X: 700 ppm≥photopolymerization initiator content

TABLE 2

| | | Reaction | Reaction | Content of |
|---|---|---|---|---|
| | | rate of | rate of | photopoly- |
| | | upper | lower | merization |
| | Outgas | silicone | silicone | tranferred to |
| | content | encapasulant | encapasulant | encapsulant |
| Comparative | X | Δ | Δ | X |
| Example 1 | | | | |
| Comparative | X | Δ | Δ | X |
| Example 2 | | | | |
| Comparative | X | Δ | Δ | X |
| Example 3 | | | | |
| Comparative | X | Δ | Δ | X |
| Example 4 | | | | |
| Comparative | ⊚ | ⊚ | ⊚ | ⊚ |
| Example 5 | | | | |
| Comparative | X | X | X | X |
| Example 6 | | | | |
| Comparative | X | Δ | Δ | X |
| Example 7 | | | | |
| Example 1 | ⊚ | ⊚ | ⊚ | ⊚ |
| Example 2 | ⊚ | ⊚ | ⊚ | ⊚ |
| Example 3 | ◯ | ⊚ | ⊚ | ⊚ |
| Example 4 | ⊚ | ⊚ | ⊚ | ⊚ |
| Example 5 | ◯ | ⊚ | ⊚ | ⊚ |
| Example 6 | ◯ | ⊚ | ⊚ | ⊚ |
| Example 7 | ◯ | ⊚ | ⊚ | ⊚ |
| Example 8 | ◯ | ⊚ | ⊚ | ⊚ |
| Example 9 | ◯ | ⊚ | ⊚ | ⊚ |
| Example 10 | ◯ | ⊚ | ⊚ | ⊚ |

Referring to Table 2, the outgas contents of Examples 1 to 10 including Photopolymerization Initiator 1 or 2 were significantly lower than those of Comparative Examples 1 to 4, 6, and 7. This significant reduction in photopolymerization initiator outgas could solve the yellowing of the silicone encapsulant and greatly increase the reaction rate of the silicone encapsulant. The reduction in the content of the photopolymerization initiator transferred to the silicone encapsulant could improve the long-term reliability and stability of a product.

In Comparative Examples 1 to 4, 6, and 7 using TPO as a photopolymerization initiator, the photopolymerization initiator TPO as transferred to remain in a content of 700 ppm or more in the silicone encapsulant, resulting in decreases in reflectance and reaction rate of the silicone encapsulant, along with problems associated with long-term reliability of a product, as described above.

In Examples 1 and 2 using only Omnipol TP as a photopolymerization initiator, the content of outgas of the photopolymerization initiator and the content of the photopolymerization initiator transferred to the silicone encapsulant were significantly reduced, thereby maintaining high reflectance, increasing reaction rates of encapsulant regions, and improving long-term reliability and stability of a product.

In Examples 3 to 10 using Omnirad TPO L as a photopolymerization initiator, the content of outgas and the content of the photopolymerization initiator transferred to the silicone encapsulant were significantly reduced, thereby maintaining high reflectance, increasing reaction rates of encapsulant regions, and improving long-term reliability and stability of a product.

Next, a protective film (PF) was formed on the silicone encapsulant and maintained at a temperature of 40 °C/a humidity of 90% for 24 hours, and only the protective film was peeled off. Thereafter, the content of the photopolymerization initiator transferred to the protective film was measured using gel permeation chromatography, and is shown in Table 3 below.

### (Evaluation of Photopolymerization Initiator Content)

⊚: photopolymerization initiator content<500 ppm
∘: 500 ppm≥photopolymerization initiator content<2,000 ppm
Δ: 2,000 ppm≥photopolymerization initiator content<4,000 ppm
X: 4,000 ppm≥photopolymerization initiator content

TABLE 3

| | Content of photopolymerization |
|---|---|
| | tranferred to protective film |
| Comparative Example 1 | Δ |
| Comparative Example 2 | Δ |
| Comparative Example 3 | Δ |
| Comparative Example 4 | Δ |
| Comparative Example 5 | ⊚ |
| Comparative Example 6 | X |
| Comparative Example 7 | Δ |
| Example 1 | ⊚ |
| Example 2 | ⊚ |
| Example 3 | ⊚ |
| Example 4 | ⊚ |
| Example 5 | ⊚ |
| Example 6 | ⊚ |
| Example 7 | ⊚ |
| Example 8 | ⊚ |
| Example 9 | ⊚ |
| Example 10 | ⊚ |

Referring to Table 3 together with Table 2, the contents of outgas of Examples 1 to 10 including Photopolymerization Initiator 1 or 2 was significantly lower than that of Comparative Examples 1 to 4, 6, and 7 including other photopolymerization initiators, and thus the contents of the photopolymerization initiators transferred not only to the silicone encapsulant but also to the protective film were greatly reduced. Specifically, compared with Comparative Examples 1 to 4, 6, and 7, Examples 1 to 10 showed a significant reduction in the photopolymerization initiator transferred to the protective film (PF). This indicates that the use of photopolymerization initiators represented by Chemical Formulas 1 and 2 reduces outgassing, and the reduced outgas prevents the transfer of the photopolymerization initiators to the silicone encapsulant and the protective film, and therefore, the use of photopolymerization initiators defined in the present disclosure can increase the reflectance and improves the reaction rate and curing degree of the silicone encapsulant, thereby improving long-term reliability.

### Evaluation Example 2: BHAST Test

Each of the dry films prepared in Examples 3 and 4 and Comparative Examples 1 to 4 was laminated on a substrate with comb-shaped electrodes (line/space=50 μm/50 μm), by using a vacuum laminator (CVP-300, Nichigo-Morton) with a first chamber of a temperature 60 °C under the conditions of a vacuum pressure of 3 hPa and a vacuum time of 10 seconds, and then pressed under the conditions of a press pressure of 0.2 MPa and a press time of 10 seconds, thereby obtaining an evaluation substrate. The PET film was peeled off, and then exposure was performed using a DI exposure apparatus (Screen) at an exposure dose obtained at 23 steps in the Step Tablet (41 steps), followed by development (1 mass % Na₂CO₃, 30 °C, 0.2 MPa) for 60 seconds, thereby completing substrate manufacturing. After completing substrate manufacturing, the substrate was subjected to BHAST for 250 hours at 110 °C, 85%, and 20V in a chamber to evaluate insulation reliability, BHAST resistance, reflectance, and the like.

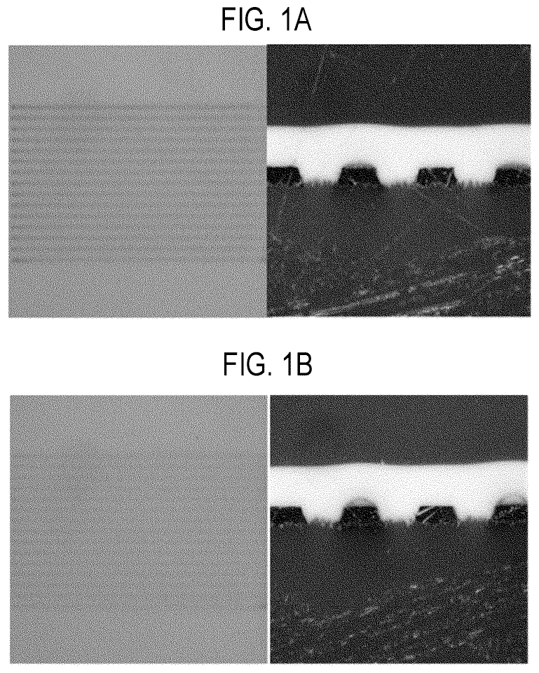

The BHAST test results are shown in FIGS. 1A and 1B.

After the BHAST test, the reflectance was measured and is shown in Table 4 below. The reflectance was measured at a wavelength of 450 nm by using a spectrophotometer (CM-2600d, Konica Minolta Sensing Co., Ltd.).
⊚: 90%≥reflectance
∘: 87%≥reflectance<90%
Δ: 84%≥reflectance<87%
X: reflectance<84%

Additionally, the HAST resistance test was performed, and then the results are shown in Table 4 below.

Each of the dry films prepared in the examples and comparative examples was laminated on a substrate with comb-shaped electrodes (line/space=50 μm/50 μm), by using a vacuum laminator (CVP-300, Nichigo-Morton Co., Ltd.) with a first chamber of a temperature 60 °C under the conditions of a vacuum pressure of 3 hPa and a vacuum time of 10 seconds, and then pressed under the conditions of a press pressure of 0.2 MPa and a press time of 10 seconds, thereby obtaining an evaluation substrate.

The PET film was peeled off, and then exposure was performed at 300 mJ/cm² measured by an integrated photometer. Then, development was performed with a 1.0% Na₂CO₃ aqueous solution at 30 °C for 60 seconds under the condition of a spray pressure of 0.2 MPa, and a cured coating film of the dry film, cured in an oven at 150 °C for 60 minutes, was formed to manufacture a HAST evaluation substrate. The evaluation substrate was placed in a high-temperature and high-humidity bath under an atmosphere of a temperature of 110 °C and a humidity of 85%, charged with a voltage of 20 V, and subjected to a highly accelerated stress test (HAST) in the bath for 250 hours. After 250 hours, the discoloration and elution of the cured coating film of the dry film were evaluated according to the following evaluation standard (Equipment Manufacturer: Espec Co., Ltd., Ion migration system, Equipment Name: NY IM1064).
∘: Peeling, discoloration, or elution was not observed.
X: Peeling, discoloration, or elution was frequently observed with the naked eye.

TABLE 4

| | Reflectance | Reflectance | |
|---|---|---|---|
| | Substrate: | Substrate: FR-4 | |
| | Cu electrode | substrate | BHAST resistance |
| Comparative | Δ | ◯ | X |
| Example 1 | | | |
| Comparative | X | Δ | X |
| Example 2 | | | |
| Comparative | X | X | X |
| Example 3 | | | |
| Comparative | X | X | X |
| Example 4 | | | |
| Example 3 | ◯ | ⊚ | ◯ |
| Example 4 | ◯ | ◯ | ◯ |

Referring to Table 4, the reflectance after the HAST test was higher in Examples 3 and 4 compared with Comparative Examples 1 to 4. Additionally, compared with Comparative Examples 1 to 4, Examples 3 and 4 showed higher reflectance, very low degrees of copper oxidation and corrosion, and no peeling, discoloration, or dissolution, after the HAST test.

### Evaluation Example 3: Reflectance Test (after Reflow and UV Treatment)

Each of the dry films prepared in Examples 1 to 4 and Comparative Examples 1 to 7 was laminated on a copper substrate by using a vacuum laminator (CVP-300, Nichigo-Morton Co., Ltd.) with a first chamber of a temperature 60 °C under the conditions of a vacuum pressure of 3 hPa and a vacuum time of 10 seconds, and then pressed under the conditions of a press pressure of 0.2 MPa and a press time of 10 seconds.

The PET film was peeled off, and then exposure was performed using a DI exposure apparatus manufactured by Screen Co., Ltd., at 300 mJ/cm² measured by an integrated photometer, while setting 23 steps using the Kodak Step Tablet No. 2, (41 steps), as a photomask. Then, development was performed with a 1% Na₂CO₃ aqueous solution at 30 °C for 60 seconds under the condition of a spray pressure of 0.2 MPa, and curing was performed for 60 seconds in an oven at 150 °C, thereby obtaining a substrate. The coating film surface of the obtained substrate was measured for the reflectance at a wavelength of 450 nm by using a spectrophotometer (CM-2600d, Konica Minolta Sensing Co., Ltd.). The reflow was performed at 260′C one to three times for 10 seconds, and the reflectance was measured. The results are shown in Table 5. After post-curing, UV was passed through an integrated photometer under conditions of 500 mJ/cm² three times, and the reflectance was measured for each time. The results are shown in Table 6.
⊚: 90%≥Reflectance
∘: 87%≥Reflectance<90%
Δ: 84%≥Reflectance<87%
X: Reflectance<84%

TABLE 5

| | | | | | Average | 450 nm |
|---|---|---|---|---|---|---|
| | Lab | | | | reflectance | reflectance |
| | Process | L | a | b | (%) | (%) |
| Example 1 | Initial | 97.23 | −1.54 | 1.99 | ⊚ | ⊚ |
| | After one reflow | 97.07 | −1.5 | 2.47 | ⊚ | ⊚ |
| | One reflow + Firing | 96.92 | −1.32 | 2.67 | ⊚ | ⊚ |
| Example 2 | Initial | 97.22 | −1.56 | 1.93 | ⊚ | ⊚ |
| | After one reflow | 97.16 | −1.55 | 2.46 | ⊚ | ⊚ |
| | One reflow + Firing | 97.04 | −1.5 | 2.63 | ⊚ | ⊚ |
| Example 3 | Initial | 97.08 | −1.58 | 1.91 | ⊚ | ⊚ |
| | After one reflow | 97.09 | −1.52 | 2.66 | ⊚ | ⊚ |
| | One reflow + Firing | 96.95 | −1.5 | 2.76 | ⊚ | ⊚ |
| Example 4 | Initial | 97.17 | −1.58 | 1.95 | ⊚ | ⊚ |
| | After one reflow | 97.12 | −1.49 | 2.85 | ⊚ | ⊚ |
| | One reflow + Firing | 96.99 | −1.4 | 2.97 | ⊚ | ⊚ |
| Comparative | Initial | 97.01 | −1.74 | 1.99 | ⊚ | ⊚ |
| Example 1 | After one reflow | 96.93 | −1.7 | 2.62 | ⊚ | ⊚ |
| | One reflow + Firing | 96.83 | −1.6 | 3.11 | ◯ | ◯ |
| Comparative | Initial | 90.89 | −1.63 | 5.72 | Δ | Δ |
| Example 2 | After one reflow | 90.85 | −1.62 | 5.94 | Δ | Δ |
| | One reflow + Firing | 90.72 | −1.58 | 6.42 | Δ | X |
| Comparative | Initial | 90.73 | −1.56 | 5.99 | Δ | Δ |
| Example 3 | After one reflow | 90.71 | −1.53 | 6.32 | Δ | Δ |
| | One reflow + Firing | 90.34 | −1.5 | 6.33 | Δ | X |
| Comparative | Initial | 88.12 | −1.61 | 9.99 | X | X |
| Example 4 | After one reflow | 87.79 | −1.6 | 10.22 | X | X |
| | One reflow + Firing | 87.34 | −1.58 | 11.32 | X | X |
| Comparative | Initial | 90.59 | −1.43 | 6.12 | Δ | Δ |
| Example 5 | After one reflow | 90.45 | −1.42 | 6.42 | Δ | Δ |
| | One reflow + Firing | 90.12 | −1.28 | 6.71 | Δ | X |
| Comparative | Initial | 90.69 | −1.63 | 5.72 | Δ | Δ |
| Example 6 | After one reflow | 90.55 | −1.62 | 5.94 | Δ | Δ |
| | One reflow + Firing | 90.32 | −1.58 | 6.39 | Δ | Δ |
| Comparative | Initial | 95.71 | −1.43 | 1.71 | ⊚ | ◯ |
| Example 7 | After one reflow | 95.51 | −1.42 | 2.37 | ◯ | ◯ |
| | One reflow + Firing | 95.42 | −1.4 | 3.01 | ◯ | Δ |

The initial reflectance without the execution of a reflow process as well as the reflectances at 450 nm after a reflow process one, two, and three times and after a reflow process once and a firing process in Examples 1 to 4 were higher than those in Comparative Examples 1 to 7, indicating that the reduction in reflectance after reflow or firing was minimized.

Particularly, as for Examples 1 to 4, Omnipol TP or Omnirad TPO-L was used as a photopolymerization initiator, resulting in a small amount of outgas, which has little effect on the silicone encapsulant, so the firing process can be omitted. Therefore, a high reflectance can be obtained even after reflow.

However, as for Comparative Examples 1 to 7, for application to backlight unit products, a firing process for TPO removal needed to be performed after the reflow process since the TPO photopolymerization initiator affected curability with the silicone encapsulant. Additionally, the execution of a firing process resulted in a large reduction in reflectance.

In conclusion, compared with Comparative Examples 1 to 7, Examples 1 to 4 showed excellent reflectance at an equivalent or higher level even when applied to actual products, and as previously discussed in Table 2, showed excellent reaction rates and curing degrees of the silicone encapsulant, thereby improving long-term durability and stability of the products.

TABLE 6
Evaluation of reflectances after post-curing and UV treatment

| | Lab (color difference) | | | | | |
|---|---|---|---|---|---|---|
| | Number of | | | | Average | 450 nm |
| | times of UV | | | | reflectance | reflectance |
| | treatment | L | a | b | (%) | (%) |
| Example 1 | 0 | 97.23 | −1.54 | 1.83 | ⊚ | ⊚ |
| | 1 | 97.11 | −1.49 | 2.27 | ⊚ | ⊚ |
| | 2 | 97 | −1.45 | 2.35 | ⊚ | ⊚ |
| | 3 | 96.8 | −1.38 | 2.64 | ⊚ | ⊚ |
| Example 2 | 0 | 97.22 | −1.56 | 1.82 | ⊚ | ⊚ |
| | 1 | 97.1 | −1.51 | 2.25 | ⊚ | ⊚ |
| | 2 | 97.01 | −1.5 | 2.32 | ⊚ | ⊚ |
| | 3 | 96.81 | −1.41 | 2.62 | ⊚ | ⊚ |
| Example 3 | 0 | 97.08 | −1.58 | 1.82 | ⊚ | ⊚ |
| | 1 | 97.01 | −1.4 | 2.25 | ⊚ | ⊚ |
| | 2 | 96.95 | −1.33 | 2.3 | ⊚ | ⊚ |
| | 3 | 96.81 | −1.3 | 2.62 | ⊚ | ⊚ |
| Example 4 | 0 | 97.17 | −1.58 | 1.8 | ⊚ | ⊚ |
| | 1 | 97.08 | −1.5 | 2.25 | ⊚ | ⊚ |
| | 2 | 96.89 | −1.45 | 2.27 | ⊚ | ⊚ |
| | 3 | 96.8 | −1.33 | 2.6 | ⊚ | ⊚ |
| Comparative | 0 | 97.01 | −1.74 | 1.98 | ⊚ | ⊚ |
| Example 1 | 1 | 96.99 | −1.7 | 2.3 | ⊚ | ⊚ |
| | 2 | 96.85 | −1.62 | 2.62 | ◯ | ⊚ |
| | 3 | 96.7 | −1.6 | 2.8 | ◯ | ◯ |
| Comparative | 0 | 90.89 | −1.63 | 3.97 | Δ | Δ |
| Example 2 | 1 | 90.79 | −1.62 | 4.03 | Δ | Δ |
| | 2 | 90.65 | −1.53 | 4.22 | Δ | X |
| | 3 | 90.53 | −1.49 | 4.35 | Δ | X |
| Comparative | 0 | 90.73 | −1.7 | 4.01 | Δ | Δ |
| Example 3 | 1 | 90.7 | −1.62 | 4.07 | Δ | Δ |
| | 2 | 90.61 | −1.58 | 4.35 | Δ | X |
| | 3 | 90.52 | −1.55 | 4.38 | Δ | X |
| Comparative | 0 | 88.12 | −1.61 | 7.02 | X | X |
| Example 4 | 1 | 88.07 | −1.59 | 7.5 | Δ | X |
| | 2 | 88.03 | −1.55 | 8.12 | Δ | X |
| | 3 | 87.99 | −1.51 | 8.25 | Δ | X |
| Comparative | 0 | 90.59 | −1.41 | 6.12 | Δ | Δ |
| Example 5 | 1 | 90.39 | −1.42 | 6.33 | Δ | Δ |
| | 2 | 90.25 | −1.43 | 6.45 | Δ | Δ |
| | 3 | 90.13 | −1.39 | 6.61 | Δ | X |
| Comparative | 0 | 90.69 | −1.33 | 5.72 | ◯ | Δ |
| Example 6 | 1 | 90.59 | −1.32 | 5.82 | Δ | Δ |
| | 2 | 90.45 | −1.33 | 5.89 | Δ | Δ |
| | 3 | 90.23 | −1.29 | 5.99 | Δ | Δ |
| Comparative | 0 | 95.71 | −1.43 | 1.71 | ⊚ | ◯ |
| Example 7 | 1 | 94.9 | −1.42 | 1.69 | ◯ | ◯ |
| | 2 | 94.7 | −1.41 | 1.66 | ◯ | ◯ |
| | 3 | 94.5 | −1.4 | 1.65 | ◯ | Δ |

As for the reflectance at 450 nm, Examples 1 to 4 showed higher initial reflectance than Comparative Examples 1 to 6, and showed a similar tendency even after treatment with UV three times at 500 mJ. The reflectance of Examples 1 to 4 after UV treatment three times were 90.2 to 90.6, but the reflectance of Comparative Examples 1 to 4 after UV treatment three times were 73 to 89.7, which might be caused by worsening yellowing.

### Evaluation Example 4: Test in Chamber at Temperature of 85 °C and Humidity of 85% and Reflectance Test in HS Chamber

Each of the dry films prepared in Examples 2 to 4 and Comparative Example 1 was laminated by using a vacuum laminator (CVP-300, Nichigo-Morton Co., Ltd.) with a first chamber of a temperature 60 °C under the conditions of a vacuum pressure of 3 hPa and a vacuum time of 10 seconds, and then pressed under the conditions of a press pressure of 0.2 MPa and a press time of 10 seconds, thereby obtaining an evaluation substrate.

The PET film was peeled off, and then exposure was performed at 300 mJ/cm² measured by an integrated photometer. Then, development was performed with a 1.0% Na₂CO₃ aqueous solution at 30 °C for 60 seconds under the condition of a spray pressure of 0.2 MPa, and curing was performed in an oven at 150 °C for 60 minutes, thereby obtaining a substrate. The obtained substrate was placed in a chamber (HIFLEX, temperature and humidity chamber, by ETAC) under the conditions of a temperature of 85 °C and a humidity of 85% and was left for 1000 hours. The substrate left in the HS chamber for 1000 hours was measured for the reflectance at a wavelength of 450 nm by using a spectrophotometer (CM-2600d, Konica Minolta Sensing Co., Ltd.). The results are shown in Table 7.
⊚: 90%≥Reflectance
∘: 87%≥Reflectance<90%
Δ: 84%≥Reflectance<87%
X: Reflectance<84%

TABLE 7
Evaluation of reflectance after left in chamber at
temperature of 85 °C and humidity of 85%

| | | | | | |
|---|---|---|---|---|---|
| | | | | Average | 450 nm reflectance |
| Time | L | a | b | reflectance | (%) |

Example 2

| | | | | | |
|---|---|---|---|---|---|
| 0 | 96.48 | −0.92 | 2.33 | ⊚ | ⊚ |
| 168 | 95.93 | −0.87 | 2.01 | ⊚ | ⊚ |
| 350 | 95.84 | −0.82 | 2.15 | ⊚ | ⊚ |
| 500 | 95.44 | −0.78 | 2.4 | ⊚ | ⊚ |
| 750 | 95.12 | −0.76 | 2.58 | ⊚ | ◯ |
| 1000 | 95.05 | −0.81 | 2.93 | ◯ | ◯ |

Example 3

| | | | | | |
|---|---|---|---|---|---|
| 0 | 96.68 | −0.87 | 1.91 | ⊚ | ⊚ |
| 168 | 96.43 | −0.82 | 2 | ⊚ | ⊚ |
| 350 | 96.14 | −0.77 | 2.13 | ⊚ | ⊚ |
| 500 | 95.94 | −0.73 | 2.39 | ⊚ | ⊚ |
| 750 | 95.82 | −0.71 | 2.58 | ⊚ | ⊚ |
| 1000 | 95.42 | −0.76 | 2.92 | ⊚ | ◯ |

Example 4

| | | | | | |
|---|---|---|---|---|---|
| 0 | 96.75 | −0.87 | 1.94 | ⊚ | ⊚ |
| 168 | 96.66 | −0.82 | 2.04 | ⊚ | ⊚ |
| 350 | 96.16 | −0.77 | 2.16 | ⊚ | ⊚ |
| 500 | 95.84 | −0.73 | 2.52 | ⊚ | ⊚ |
| 750 | 95.03 | −0.71 | 2.78 | ⊚ | ◯ |
| 1000 | 95.01 | −0.76 | 3.1 | ◯ | ◯ |

Comparative Example 1

| | | | | | |
|---|---|---|---|---|---|
| 0 | 96.48 | −0.87 | 2.12 | ⊚ | ⊚ |
| 168 | 95.93 | −0.82 | 2.1 | ⊚ | ⊚ |
| 350 | 95.64 | −0.77 | 2.29 | ⊚ | ⊚ |
| 500 | 95.14 | −0.73 | 2.69 | ⊚ | ⊚ |
| 750 | 94.82 | −0.71 | 2.95 | ◯ | ◯ |
| 1000 | 94.75 | −0.76 | 3.3 | ◯ | Δ |

Even when evaluated for a long period of time under the conditions of high temperature and humidity, Examples 2 to 4 showed a small reduction in the reflectance at 450 nm even under the conditions of high temperature and high humidity.

The b value after evaluation under the conditions of high temperature and high humidity was smaller in Examples 2 to 4 than Comparative Example 1. This indicates that Examples 2 to 4 underwent less yellowing compared with Comparative Example 1 under the conditions of high temperature and high humidity. Examples 2 to 4 underwent less yellowing compared with Comparative Example 1 even under the conditions of high temperature and high humidity, and thus can be more advantageously used as materials for backlight units.

### Evaluation Example 5: Evaluation of General Properties

### <Manufacturing of Evaluation Substrate>

Each of the photosensitive resin compositions prepared in the examples and comparative examples was laminated on a PET film by using a vacuum laminator (CVP-300, Nichigo-Morton Co., Ltd.) with a first chamber of a temperature 60 °C under the conditions of a vacuum pressure of 3 hPa and a vacuum time of 10 seconds, and then pressed under the conditions of a press pressure of 0.2 MPa and a press time of 10 seconds, thereby obtaining an evaluation substrate. The PET film was peeled off, and then exposure was performed using a DI exposure apparatus manufactured by Screen Co., Ltd., at 300 mJ/cm² measured by an integrated photometer, while setting 23 steps using the Kodak Step Tablet No. 2, (41 steps), as a photomask. Then, development was performed with a 1% Na₂CO₃ aqueous solution at 30 °C for 60 seconds under the condition of a spray pressure of 0.2 MPa, and post-curing was performed in an oven at 150 °C, thereby manufacturing a substrate.

### <Pencil Hardness>

For the substrate, pencils from B to 9H, which had been polished so that the end of the core was flattened, were pressed at an angle of about 450 to record the hardness of the pencils without peeling of the coating film.

### <Adhesion>

Checkboard squares of 1 mm (10×10) were marked on the substrate, and a transparent adhesive tape was fully attached onto the checkerboard squares, and one end of the tape was immediately peeled off while being held at a right angle to the substrate, and the number of checkboard squares that were not completely peeled off was then checked. The results were recorded using the number of remaining checkboard squares as the numerator and the total number of checkboard squares (100 ea) as the denominator.
PASS: At least 95% of checkboard squares remained.
NG: Less than 95% of checkboard squares remained.

### <Gloss Evaluation>

The coating film surface of the substrate was measured for gloss at an angle of 600 was measured using a gloss colorimeter (BYK E-4430).

### <Solder Heat Resistance>

The substrate was immersed in a solder bath at 288 °C for 10 seconds. Thereafter, checkboard squares of 1 mm (10×10) were marked on the substrate, and a transparent adhesive tape was fully attached onto the checkerboard squares, and one end of the tape was immediately peeled off while being held at a right angle to the substrate, and the number of checkboard squares that were not completely peeled off was then checked. The results were recorded using the number of remaining checkboard squares as the numerator and the total number of checkboard squares (100 ea) as the denominator.
PASS: At least 95% of checkboard squares remained.
NG: Less than 95% of checkboard squares remained.

TABLE 8

| | | | | | | | | | Compar- |
|---|---|---|---|---|---|---|---|---|---|
| | | | | | | | | | ative |
| Evaluation | Exam- | Exam- | Exam- | Exam- | Exam- | Exam- | Exam- | Exam- | Exam- |
| item | ple 1 | ple 2 | ple 3 | ple 4 | ple 5 | ple 6 | ple 7 | ple 8 | ple 1 |
| Pencil | 7H | 7H | 7H | 7H | 7H | 7H | 6H | 6H | 7H |
| hardness | | | | | | | | | |
| Adhesion | 100/ | 100/ | 100/ | 100/ | 100/ | 100/ | 100/ | 100/ | 100/ |
| | 100 | 100 | 100 | 100 | 100 | 100 | 100 | 100 | 100 |
| | PASS | PASS | PASS | PASS | PASS | PASS | PASS | PASS | PASS |
| Gloss | 89.1 | 89.5 | 90.1 | 89.7 | 88.9 | 88.7 | 73.0 | 86.3 | 86.2 |
| Solder | PASS | PASS | PASS | PASS | PASS | PASS | PASS | PASS | PASS |
| heat | | | | | | | | | |
| resistance | | | | | | | | | |

| | Compar- | Compar- | Compar- | Compar- | Compar- | Compar- |
|---|---|---|---|---|---|---|
| | ative | ative | ative | ative | ative | ative |
| Evaluation | Exam- | Exam- | Exam- | Exam- | Exam- | Exam- |
| item | ple 2 | ple 3 | ple 4 | ple 5 | ple 6 | ple 7 |
| Pencil | 6H | 6H | 6H | 3H | 7H | 3H |
| hardness | | | | | | |
| Adhesion | 100/ | 100/ | 100/ | NG | 100/ | NG |
| | 100 | 100 | 100 | | 100 | |
| | PASS | PASS | PASS | | PASS | |
| Gloss | 85.3 | 85.7 | 85.2 | 72 | 89.5 | 50 |
| Solder | PASS | PASS | PASS | NG | PASS | NG |
| heat | | | | | | |
| resistance | | | | | | |

Comparative Example 5 had a small content of the photopolymerization initiator, resulting in incomplete surface curing, thus showing a pencil hardness as low as 3H, a significantly reduced gloss to 72, adhesion and solder heat resistance being NG, and unfavorable developability. Comparative Example 6 had a too high content of the photopolymerization initiator, resulting in favorable surface curing to ensure excellent adhesion or solder heat resistance, but poor developability due to increased curability, which might cause problems in the formation of SRO. Example 7 showed an improved pencil hardness as high as 6H and significantly improved adhesion and solder heat resistance, and Example 8 showed an improved pencil hardness as high as 6H and significantly improved adhesion and solder heat resistance.

### Evaluation Example 6: Analysis of Phosphorus Content of Photosensitive Resin Composition

1) Each of the photosensitive resin compositions of Examples 1 to 8 and Comparative Examples 1 to 6 was accurately weighed to 0.1 g in a beaker, and then 2 mL of nitric acid was added, followed by heating on a hot plate to conduct the reaction. 2) The specimen was temporarily placed on a hot plate and cooled to room temperature, and 0.03 mL of hydrochloric acid in a hot state was added to conduct the reaction. 3) Thereafter, a nitric acid solution of the specimen was not allowed to completely evaporate, with a small amount remaining. The residue was cooled to room temperature, and then completely dissolved in 1 mL of strong nitric acid that was again added. The specimen was completely dissolved and then diluted with ultrapure water. 4) The phosphorus (P) concentration for the examples and comparative examples was analyzed by using an ICP-OES analysis system (Optima series, manufactured by Perkin Elmer Co., Ltd.) under the conditions of wavelengths of 213.617 nm and 214.914 nm.

TABLE 9

| | | | | | | | | | Compar- |
|---|---|---|---|---|---|---|---|---|---|
| | | | | | | | | | ative |
| Evaluation | Exam- | Exam- | Exam- | Exam- | Exam- | Exam- | Exam- | Exam- | Exam- |
| item | ple 1 | ple 2 | ple 3 | ple 4 | ple 5 | ple 6 | ple 7 | ple 8 | ple 1 |
| Phosphorus | 2,900 | 3,101 | 3,120 | 3,103 | 3,120 | 3,050 | 3,200 | 3,220 | 3,230 |
| (P) | ppm | ppm | ppm | ppm | ppm | ppm | ppm | ppm | ppm |
| content | | | | | | | | | |

| | Compar- | Compar- | Compar- | Compar- | Compar- |
|---|---|---|---|---|---|
| | ative | ative | ative | ative | ative |
| Evaluation | Exam- | Exam- | Exam- | Exam- | Exam- |
| item | ple 2 | ple 3 | ple 4 | ple 5 | ple 6 |
| Phosphorus | 3,195 | 3,210 | 2,985 | 430 | 5,500 |
| (P) | ppm | ppm | ppm | ppm | ppm |
| content | | | | | |

The compositions of Examples 1 to 8 and Comparative Examples 1 to 4 were detected to have a phosphorous concentration of around 3,000 ppm. Comparative Example 5 was detected to have a phosphorus content as low as 430 ppm since it did not use a photopolymerization initiator containing phosphorus. Comparative Example 6 was detected to have a phosphorus content of 5,500 ppm.

1. A photosensitive resin composition comprising:
(A) a carboxyl group-containing resin not containing an aromatic ring;
(B) an inorganic filler; and
(E) a photopolymerization initiator of a trimethylbenzoyl phosphine oxide group-containing compound having at least one P—O band.

2. The photosensitive resin composition of claim 1, wherein (E) the photopolymerization initiator of a trimethylbenzoyl phosphine oxide group-containing compound having at least one P—O band comprises a *—C(═O)—P(═O)R₁—O—*′ moiety (where, R¹ is an alkyl group of 1 to 20 carbon atoms, an alkenyl group of 2 to 20 carbon atoms, an alkynyl group of 2 to 20 carbon atoms, or a cyclic group of 5 to 20 carbon atoms).

3. The photosensitive resin composition of claim 1, wherein (E) the photopolymerization initiator of a trimethylbenzoyl phosphine oxide group-containing compound having at least one P—O band is a trimethylbenzoyl phosphine oxide group-containing polymer.

4. The photosensitive resin composition of claim 3, wherein the trimethylbenzoyl phosphine oxide group-containing polymer has a weight average molecular weight (Mₙ) of 900 g/mol or more.

5. The photosensitive resin composition of claim 3, wherein the trimethylbenzoyl phosphine oxide group-containing polymer is represented by Chemical Formula 1 below: 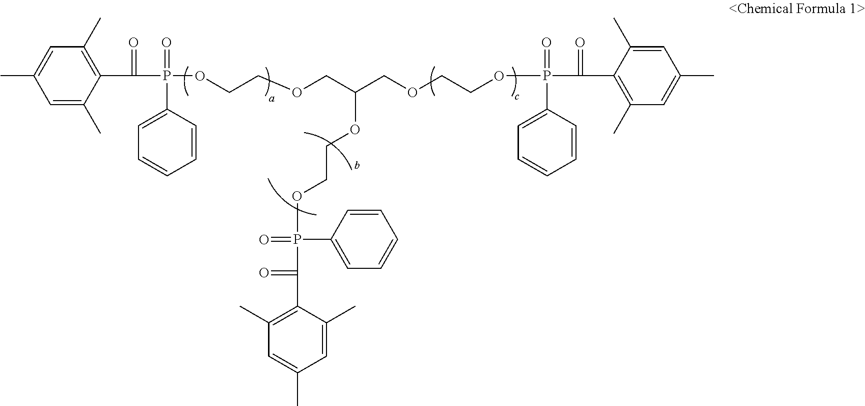
where a=0 to 100, b=0 to 100, and c=0 to 100.

6. The photosensitive resin composition of claim 1, wherein (E) the photopolymerization initiator of a trimethylbenzoyl phosphine oxide group-containing compound having at least one P—O band comprises an alkoxy group.

7. The photosensitive resin composition of claim 1, wherein (E) the photopolymerization initiator of a trimethylbenzoyl phosphine oxide group-containing compound having at least one P—O band comprises an ethoxy group.

8. The photosensitive resin composition of claim 1, wherein (E) the photopolymerization initiator of a trimethylbenzoyl phosphine oxide group-containing compound having at least one P—O band is represented by Chemical Formula 2 below:

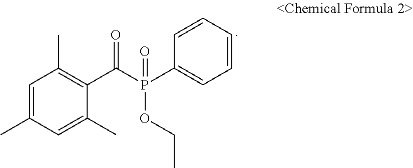 [SMILES: CCOP(=O)(C(=O)c1c(C)cc(C)cc1C)c1ccccc1]

9. The photosensitive resin composition of claim 1, wherein the content of (E) the photopolymerization initiator of a trimethylbenzoyl phosphine oxide group-containing compound having at least one P—O band is 0.01 to 10 wt % relative to the total weight of the composition.

10. The photosensitive resin composition of claim 1, wherein (A) the carboxyl group-containing resin not containing an aromatic ring has an unsaturated double bond.

11. The photosensitive resin composition of claim 1, further comprising at least one selected from the group of (C) a mercapto-modified (meth)acrylate, (D) a resin containing an aromatic ring, (F) a silane coupling agent, and (G) a resin having a urethane bond.

12-15. (canceled)

16. The photosensitive resin composition of claim 1, wherein the content of outgas measured by thermal desorption spectroscopy (TDS) and gas chromatography-mass spectrometry (GC-MS) for the photosensitive resin composition is 1,000 ppm or less relative to (E) the photopolymerization initiator of a trimethylbenzoyl phosphine oxide group-containing compound having at least one P—O band.

17. The photosensitive resin composition of claim 1, wherein the content of phosphorous is 500 to 5000 ppm.

18. A photosensitive resin composition comprising:
(A) a carboxyl group-containing resin not containing an aromatic ring;
(C) a mercapto-modified (meth)acrylate; and
(E) a photopolymerization initiator of a trimethylbenzoyl phosphine oxide group-containing compound having at least one P—O band.

19. The photosensitive resin composition of claim 18, further comprising at least one selected from the group of (D) a resin containing an aromatic ring, (F) a silane coupling agent, and (G) a resin having a urethane bond.

20-21. (canceled)

22. A dry film having a photosensitive resin layer formed by applying and drying the photosensitive resin composition of claim 1 onto a first film.

23. A cured product obtained by curing the photosensitive resin composition of claim 1 or a photosensitive resin layer for a dry film obtained from the photosensitive resin composition.

24. A printed circuit board comprising the cured product of claim 23 as a solder resist.

25. The printed circuit board of claim 24, further comprising a silicone encapsulant disposed on the solder resist,
wherein the silicone encapsulant comprises an upper encapsulant region and a lower encapsulant region, and
the content of (E) the photopolymerization initiator of a trimethylbenzoyl phosphine oxide group-containing compound having at least one P—O band comprised in at least one of the upper encapsulant region or the lower encapsulant region is 1,000 ppm or less relative to the content of (E) the photopolymerization initiator of a trimethylbenzoyl phosphine oxide group-containing compound having at least one P—O band comprised in the solder resist.

26. (canceled)

27. A laminate comprising:
the cured product of claim 23; and
a protective film,
wherein the content of (E) the photopolymerization initiator of a trimethylbenzol phosphine oxide group-containing compound having at least one P—O band comprised in the protective film is 1,000 ppm or less relative to the content of (E) the photopolymerization initiator of a trimethylbenzoyl phosphine oxide group-containing compound having at least one P—O band comprised in the solder resist.

28. (canceled)
